(19) United States
(12) Patent Application Publication
(10) Pub. No.: US 2022/0231057 A1
(43) Pub. Date: Jul. 21, 2022

(54) IMAGING DEVICE

(71) Applicant: SONY SEMICONDUCTOR SOLUTIONS CORPORATION, Kanagawa (JP)

(72) Inventor: Keisuke HATANO, Kanagawa (JP)

(73) Assignee: SONY SEMICONDUCTOR SOLUTIONS CORPORATION, Kanagawa (JP)

(21) Appl. No.: 17/614,080

(22) PCT Filed: May 27, 2020
(86) PCT No.: PCT/JP2020/020846

§ 371 Date: Nov. 24, 2021

(30) Foreign Application Priority Data
Jun. 4, 2019 (JP) 2019-104223

(51) Int. Cl. H01L 27/146

(52) U.S. Cl. CPC H01L 27/1462; H01L 27/14627; H01L 27/14643; H01L 27/14607

(57) ABSTRACT

Provided is an imaging device that makes it possible to suppress a decrease in image quality. The imaging device includes: a first semiconductor substrate including a light input surface and a photoelectric conversion section; a second semiconductor substrate on an opposite side of the first semiconductor substrate to the light input surface; an insulating film on side of the first semiconductor substrate on which the light input surface is disposed; a cut portion, a hole portion, or both that extend at least in a thickness direction of the insulating film; an implanted film in a portion or all in a depth direction of the cut portion, the hole portion, or both; a protective member opposed to the first semiconductor substrate with the insulating film in between; and a bonding member including a different material from a material of the implanted film between the protective member and the insulating film.

### TECHNICAL FIELD

The present disclosure relates to an imaging device including a semiconductor substrate.

### BACKGROUND ART

In recent years, imaging devices such as a CSP (Chip Size Package) have been developed (For example, see PTLs 1 and 2). This imaging device includes, for example, a semiconductor substrate and a protective member opposed to the semiconductor substrate. The semiconductor substrate is provided with a photoelectric conversion section such as a photodiode. The protective member is bonded to the semiconductor substrate by, for example, a bonding member including a resin material.

### CITATION LIST

### Patent Literature

PTL 1: Japanese Unexamined Patent Application Publication No. 2015-159275

PTL 2: Japanese Unexamined Patent Application Publication No. 2008-270650

### SUMMARY OF THE INVENTION

In such an imaging device, it is desired to suppress, for example, a decrease in image quality caused by flare, etc.

It is therefore desirable to provide an imaging device that makes it possible to suppress a decrease in image quality.

An imaging device according to an embodiment of the present disclosure includes: a first semiconductor substrate; a second semiconductor substrate; an insulating film; a cut portion, a hole portion, or both; an implanted film; a protective member; and a bonding member. The first semiconductor substrate includes a light input surface and is provided with a photoelectric conversion section. The second semiconductor substrate is provided on opposite side of the first semiconductor substrate to the light input surface. The insulating film is provided on side of the first semiconductor substrate on which the light input surface is disposed. The cut portion, a hole portion, or both extend at least in a thickness direction of the insulating film. The implanted film is implanted in a portion or all in a depth direction of the cut portion, the hole portion, or both. The protective member is opposed to the first semiconductor substrate with the insulating film in between. The bonding member includes a different material from a material of the implanted film and is provided between the protective member and the insulating film.

In the imaging device according to the embodiment of the present disclosure, the implanted film is implanted in a portion or all in the depth direction of the cut portion, the hole portion, or both. The implanted film includes the different material from the material of the bonding member. Thus, the bonding member between the protective member and the insulating film is formed to be thinner than in a case where the cut portion or the hole portion is filled with the use of the bonding member.

### BRIEF DESCRIPTION OF DRAWING

FIG. 1 is a block diagram illustrating an example of a functional configuration of an imaging device according to a first embodiment of the present disclosure.

FIG. 2 is a schematic view illustrating a cross-sectional configuration of a main portion of the imaging device illustrated in FIG. 1.

FIG. 3 is a schematic view illustrating another example (1) of the cross-sectional configuration of the imaging device illustrated in FIG. 2.

FIG. 4 is a schematic view illustrating another example (2) of the cross-sectional configuration of the imaging device illustrated in FIG. 2.

FIG. 5 is a schematic view illustrating a plan configuration of a cut portion illustrated in FIG. 2, etc.

FIG. 6A is a schematic cross-sectional view illustrating a process of a method of manufacturing the imaging device illustrated in FIG. 2.

FIG. 6B is a schematic cross-sectional view illustrating a process following FIG. 6A.

FIG. 6C is a schematic cross-sectional view illustrating a process following FIG. 6B.

FIG. 6D is a schematic cross-sectional view illustrating a process following FIG. 6C.

FIG. 6E is a schematic cross-sectional view illustrating a process following FIG. 6D.

FIG. 6F is a schematic cross-sectional view illustrating a process following FIG. 6E.

FIG. 6G is a schematic cross-sectional view illustrating a process following FIG. 6F.

FIG. 6H is a schematic cross-sectional view illustrating a process following FIG. 6G.

FIG. 7 is a schematic cross-sectional view illustrating a process of a method of manufacturing the imaging device illustrated in FIG. 3.

FIG. 8 is a schematic cross-sectional view illustrating a process of a method of manufacturing the imaging device illustrated in FIG. 4.

FIG. 9 is a schematic view illustrating a cross-sectional configuration of a main portion of an imaging device according to a comparative example.

FIG. 10A is a schematic view provided for description of reflected light that occurs in the imaging device illustrated in FIG. 9.

FIG. 10B is a schematic view provided for description of reflected light that occurs in the imaging device illustrated in FIG. 2.

FIG. 11 is a schematic view illustrating a cross-sectional configuration of a main portion of an imaging device according to a modification example 1.

FIG. 12A is a schematic cross-sectional view illustrating a process of a method of manufacturing the imaging device illustrated in FIG. 11.

FIG. 12B is a schematic cross-sectional view illustrating a process following FIG. 12A.

FIG. 13 is a schematic view illustrating a cross-sectional configuration of a main portion of an imaging device according to a modification example 2.

FIG. 14A is a schematic cross-sectional view illustrating a process of a method of manufacturing the imaging device illustrated in FIG. 13.

FIG. 14B is a schematic cross-sectional view illustrating a process following FIG. 14A.

FIG. 14C is a schematic cross-sectional view illustrating a process following FIG. 14B.

FIG. 14D is a schematic cross-sectional view illustrating a process following FIG. 14C.

FIG. 15 is a schematic view illustrating a cross-sectional configuration of a main portion of an imaging device according to a second embodiment of the present disclosure.

FIG. 16 is a schematic view illustrating a plan configuration of a hole portion illustrated in FIG. 15.

FIG. 17 is a schematic view illustrating another example of the cross-sectional configuration of the imaging device illustrated in FIG. 15.

FIG. 18A is a schematic cross-sectional view illustrating a process of a method of manufacturing the imaging device illustrated in FIG. 15.

FIG. 18B is a schematic cross-sectional view illustrating a process following FIG. 18A.

FIG. 19 is a schematic view illustrating a cross-sectional configuration of a main portion of an imaging device according to a modification example 3.

FIG. 20 is a schematic cross-sectional view illustrating a process of a method of manufacturing the imaging device illustrated in FIG. 19.

FIG. 21 is a block diagram illustrating an example of an electronic apparatus including the imaging device illustrated in FIG. 1, etc.

FIG. 22 is a block diagram depicting an example of a schematic configuration of an in-vivo information acquisition system.

FIG. 23 is a view depicting an example of a schematic configuration of an endoscopic surgery system.

FIG. 24 is a block diagram depicting an example of a functional configuration of a camera head and a camera control unit (CCU).

FIG. 25 is a block diagram depicting an example of schematic configuration of a vehicle control system.

FIG. 26 is a diagram of assistance in explaining an example of installation positions of an outside-vehicle information detecting section and an imaging section.

### MODES FOR CARRYING OUT THE INVENTION

In the following, some embodiments of the present disclosure are described in detail with reference to the drawings. It is to be noted that description is given in the following order.

1. First Embodiment (an imaging device including an implanted film in a cut portion, the implanted film including an insulating material)
2. Modification Example 1 (an example in which the implanted film is implanted in a portion in a depth direction of the cut portion)
3. Modification Example 2 (an example in which a planarization film is implanted in the cut portion)
4. Second Embodiment (an imaging device including an implanted film in a hole portion, the implanted film including an electrically conductive material)
5. Modification Example 3 (an example with a cut portion and a hole portion)
6. Application Example (an electronic apparatus)

### 7. Practical Application Examples

### 1. First Embodiment

### (Functional Configuration of Imaging Device 1)

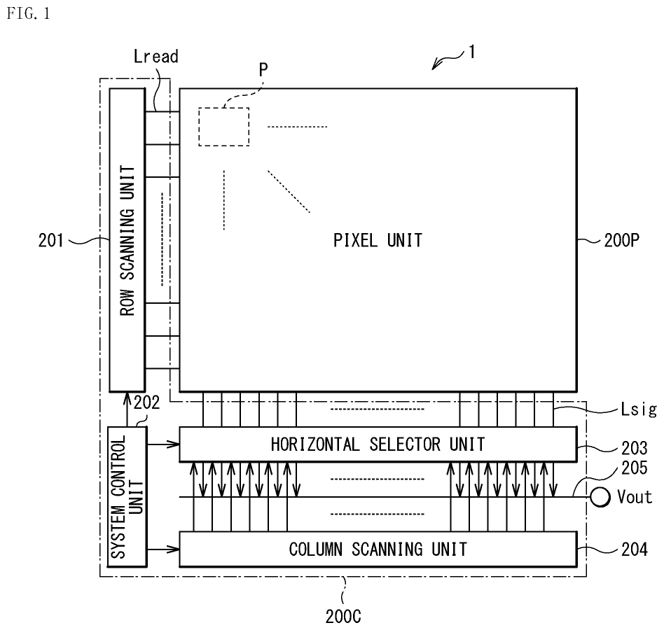

FIG. 1 illustrates an example of a functional configuration of an imaging device (imaging device 1) according to an embodiment of the present disclosure. The imaging device 1 includes a pixel unit 200P, and circuitry 200C that drives the pixel unit 200P. The pixel unit 200P includes, for example, a plurality of light-receiving unit regions (pixels P) in a two-dimensional arrangement. The circuitry 200C includes, for example, a row scanning unit 201, a horizontal selector unit 203, a column scanning unit 204, and a system control unit 202.

In the pixel unit 200P, for example, pixel drive lines Lread (for example, row selector lines and reset control lines) are wired for each pixel row, while vertical signal lines Lsig are wired for each pixel column. The pixel drive lines Lread transfer drive signals for signal reading from the pixel unit 200P. One end of each of the pixel drive lines Lread is coupled to an output terminal corresponding to an associated row of the row scanning unit 201. The pixel unit 200P includes, for example, a pixel circuit provided for each pixel P.

The row scanning unit 201 includes, for example, a shift register and an address decoder, and serves as a pixel driver that drives each pixel P of the pixel unit 200P, for example, in units of rows. Signals to be outputted from each pixel P of a pixel row selected and scanned by the row scanning unit 201 are supplied to the horizontal selector unit 203 through respective ones of the vertical signal lines Lsig. The horizontal selector unit 203 includes, for example, an amplifier and a horizontal selector switch that are provided for each of the vertical signal lines Lsig.

The column scanning unit 204 includes, for example, a shift register and an address decoder, and sequentially drives each of the horizontal selector switches of the horizontal selector unit 203 while scanning the horizontal selector switches. By the selection and scanning by the column scanning unit 204, the signals of the respective pixels P to be transferred through the respective vertical signal lines Lsig are sequentially outputted to horizontal signal lines 205. The signals outputted are inputted to, for example, an unillustrated signal processor through the respective ones of the horizontal signal lines 205.

The system control unit 202 receives, for example, a clock given from outside, and data that gives a command of an operation mode. Moreover, the system control unit 202 outputs data such as internal information of the imaging device 1. Furthermore, the system control unit 202 includes a timing generator that generates various timing signals. On the basis of the various timing signals generated in the timing generator, the system control unit 202 carries out a drive control of, for example, the row scanning unit 201, the horizontal selector unit 203, and the column scanning unit 204.

### (Configuration of Main Portion of Imaging Device 1)

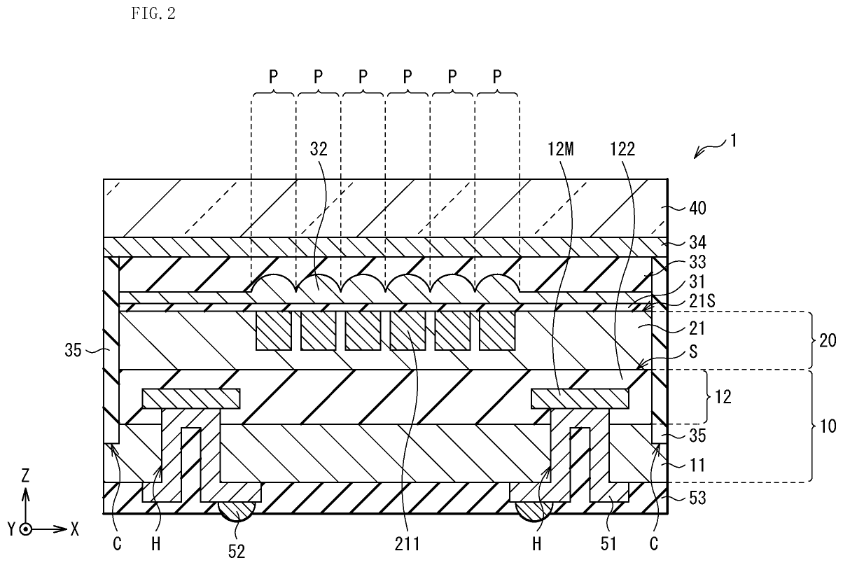

FIG. 2 is a schematic cross-sectional view illustrating a configuration of a main portion of the imaging device 1. With reference to FIG. 2, a specific configuration of the imaging device 1 is described.

The imaging device 1 is a CSP, and includes, for example, a logic chip 10, a sensor chip 20, and a protective member 40 in this order. Between the logic chip 10 and the sensor chip 20, a bonding surface S is formed. Between the sensor chip 20 and the protective member 40, an insulating film 31, a microlens 32, a planarization film 33, and a bonding member 34 are provided in this order from side on which the sensor chip 20 is disposed. For example, the imaging device 1 is configured to allow side on which the logic chip 10 is disposed to be mounted on a printed circuit board such as a mother board. On the side on which the logic chip 10 is disposed, the imaging device 1 includes a rewiring 51, a solder bump 52, and a protective resin layer 53. The logic chip 10 and the sensor chip 20 are electrically coupled by, for example, a through via (not illustrated). Instead of the through via, the logic chip 10 and the sensor chip 20 may be electrically coupled by metal direct bonding such as Cu—Cu bonding. Here, the microlens 32 corresponds to one specific example of a “lens” of the present disclosure. The solder bump 52 corresponds to one specific example of an “external coupling terminal”.

The logic chip 10 includes, for example, a semiconductor substrate 11 and a multilayered wiring layer 12, and has a stacked structure thereof. The logic chip 10 includes, for example, a logic circuit and a control circuit. An entirety of the circuitry 200C (FIG. 1) may be provided in the logic chip 10. Alternatively, a portion of the circuitry 200C may be provided in the sensor chip 20, and remainder of the circuitry 200C may be provided in the logic chip 10. Here, the semiconductor substrate 11 corresponds to one specific example of a “second semiconductor substrate” of the present disclosure, and the multilayered wiring layer 12 corresponds to one specific example of a “multilayered wiring layer” of the present disclosure.

The semiconductor substrate 11 is opposed to the protective member 40 with the multilayered wiring layer 12 and the sensor chip 20 in between. The multilayered wiring layer 12 is provided on one of main surfaces (X-Y plane) of the semiconductor substrate 11, and the rewiring 51, etc. are provided on the other of the main surfaces. The semiconductor substrate 11 includes, for example, a silicon (Si) substrate. A thickness of the semiconductor substrate 11 (dimension in a Z-axis direction) is, for example, 50 μm to 150 μm.

The multilayered wiring layer 12 is provided between the semiconductor substrate 11 and the sensor chip 20. The multilayered wiring layer 12 includes a plurality of pad electrodes 12M and an interlayer insulating film 122 that separates the plurality of the pad electrodes 12M. The pad electrode 12M includes, for example, copper (Cu) or aluminum (Al), etc. The interlayer insulating film 122 includes, for example, a silicon oxide film (SiO) or a silicon nitride film (SiN), etc. The multilayered wiring layer 12 includes a plurality of wirings (not illustrated) separated from one another by the interlayer insulating film 122. For example, the bonding surface S is provided between the multilayered wiring layer 12 and the sensor chip 10.

A hole H is provided at a predetermined position of the semiconductor substrate 11. The hole H is provided for electrical coupling of the pad electrode 12M and the rewiring 51. The hole H extends through the semiconductor substrate 11 from the other of the main surfaces of the semiconductor substrate 11 to the one of the main surfaces of the semiconductor substrate 11, and reaches the pad electrode 12M of the multilayered wiring layer 12.

The rewiring 51 is provided in the vicinity of the hole H, and covers a side wall and a bottom surface of the hole H. In the bottom surface of the hole H, the rewiring 51 is in contact with the pad electrode 12M of the multilayered wiring layer 12. The rewiring 51 is extended from the hole H to the other of the main surfaces of the semiconductor substrate 11, and is led to a region where the solder bump 52 is formed. The rewiring 51 is disposed in a selective region of the other of the main surfaces of the semiconductor substrate 11. The rewiring 51 includes, for example, copper (Cu), tungsten (W), titanium (Ti), tantalum (Ta), a titanium tungsten alloy (TiW), or polysilicon, etc. A thickness of the rewiring 51 is, for example, about several μm to several tens of

Between the rewiring 51 and the semiconductor substrate 11, an insulating film (not illustrated) is provided. The insulating film covers the side wall of the hole H from the other of the main surfaces of the semiconductor substrate 11. The insulating film includes, for example, a silicon oxide film (SiO) or a silicon nitride film (SiN), etc.

The solder bump 52 is coupled to the rewiring 51 that is led to the other of the main surfaces of the semiconductor substrate 11. The solder bump 52 serves as an external coupling terminal for mounting on a printed circuit board, and includes, for example, lead-free high melting point solder such as tin (Sn)-silver (Ag)-copper (Cu), etc. For example, a plurality of the solder bumps 52 is provided in a regular arrangement at a predetermined pitch on the other of the main surfaces of the semiconductor substrate 11. The arrangement of the solder bumps 52 is appropriately set in accordance with positions of bonding pads on the printed circuit board (not illustrated) on which the imaging device 1 is to be mounted. The solder bumps 52 are electrically coupled to the pad electrodes 12M of the multilayered wiring layer 12 through the rewiring 51. Other external coupling terminals may be used instead of the solder bumps 52. For example, the external coupling terminals may include a metal film such as copper (Cu) or nickel (Ni), etc. formed using a plating method.

The protective resin layer 53 provided on the other of the main surfaces of the semiconductor substrate 11 is provided for protection of the rewiring 51. The protective resin layer 53 has an opening that makes a portion of the rewiring 51 exposed. The solder bump 52 is disposed in the opening of the protective resin layer 53. That is, the solder bump 52 is coupled to the rewiring 51 in a portion exposed from the protective resin layer 53. The protective resin layer 53 is, for example, a solder resist, and includes an epoxy based resin, a polyimide based resin, a silicon based resin, or an acrylic resin, etc.

The sensor chip 20 provided between the logic chip 10 and the protective member 40 includes, for example, a multilayered wiring layer (not illustrated) and a semiconductor substrate 21 in this order from side on which the logic chip 10 is disposed. Here, the semiconductor substrate 21 corresponds to one specific example of a “first semiconductor substrate” of the present disclosure.

The multilayered wiring layer of the sensor chip 20 is in contact with the multilayered wiring layer 12 of the logic chip 10. Between them, for example, the bonding surface S between the sensor chip 20 and the logic chip 10 is provided. The multilayered wiring layer of the logic chip 10 includes a plurality of wirings, and an interlayer insulating film that separates the plurality of the wirings. In the multilayered wiring layer of the sensor chip 20, for example, the pixel circuit of the pixel unit 200P (FIG. 1) is provided.

The semiconductor substrate 21 includes, for example, a silicon (Si) substrate. The semiconductor substrate 21 is provided with a light input surface 21S. For example, one of main surfaces of the semiconductor substrate 21 constitutes the light input surface 21S. On the other of the main surfaces, the multilayered wiring layer is provided. In the semiconductor substrate 21 of the sensor chip 20, a photodiode (PD) 211 is provided for each pixel P. The PD 211 is provided in the vicinity of the light input surface 21S of the semiconductor substrate 21. Here, the PD 211 corresponds to one specific example of a “photoelectric conversion section” of the present disclosure.

The insulating film 31 provided between the semiconductor substrate 21 and the microlens 32 has a function of planarizing the light input surface 21S of the semiconductor substrate 21. The insulating film 31 includes, for example, silicon oxide (SiO), etc. Here, the insulating film 31 corresponds to one specific example of an “insulating film” of the present disclosure.

The microlens 32 on the insulating film 31 is provided for each pixel P, at a position opposed to the PD 211 of the sensor chip 20. The microlens 32 is configured to collect light entering the microlens 32, on the PD 211 for each pixel P. A lens system of the microlens 32 is set to a value corresponding to a size of the pixel P. Examples of a lens material of the microlens 32 include a silicon oxide film (SiO) and a silicon nitride film (SiN), etc. The microlens 32 may include an organic material. A material constituting the microlens 32 is provided in, for example, a film shape outside the pixel unit 200P. A color filter may be provided between the microlens 32 and the insulating film 31.

The planarization film 33 is provided between the microlens 32 and the bonding member 34. The planarization film 33 is provided over substantially an entire surface of the light input surface 21S of the semiconductor substrate 21, to cover the microlens 32. This leads to planarization of the light input surface 21S of the semiconductor substrate 21 on which the microlens 32 is provided. The planarization film 33 includes, for example, a silicon oxide film (SiO) or a resin material. Examples of the resin material includes an epoxy based resin, a polyimide based resin, a silicon based resin, and an acrylic resin. For example, the planarization film 33 is provided with a cut portion C along a thickness direction.

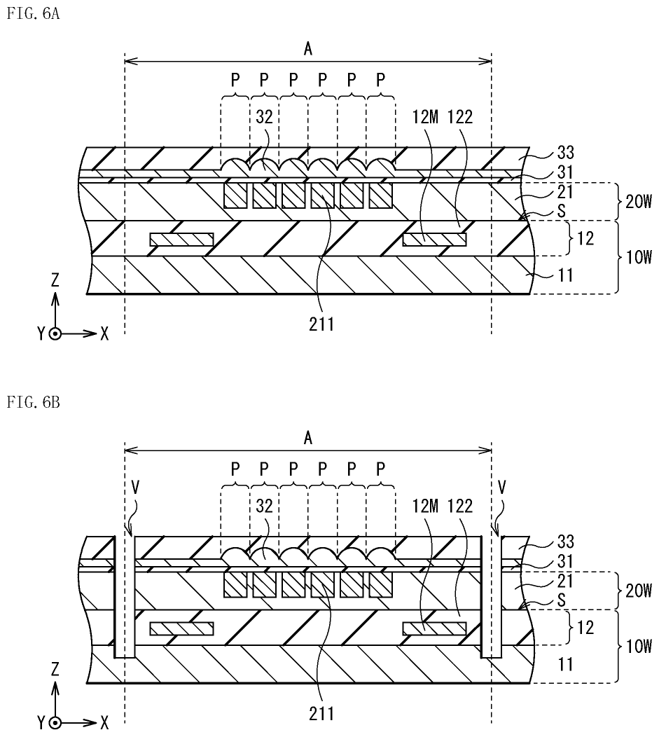

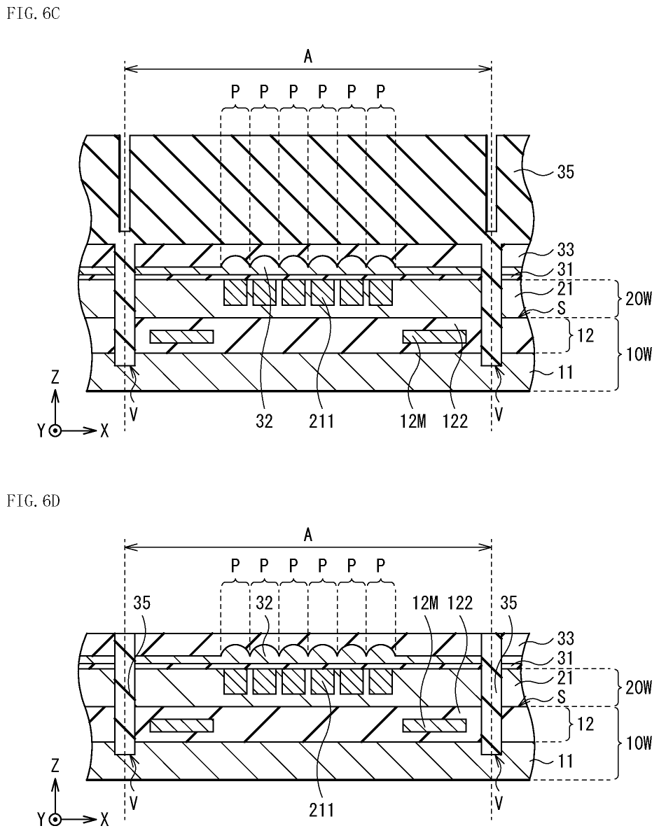

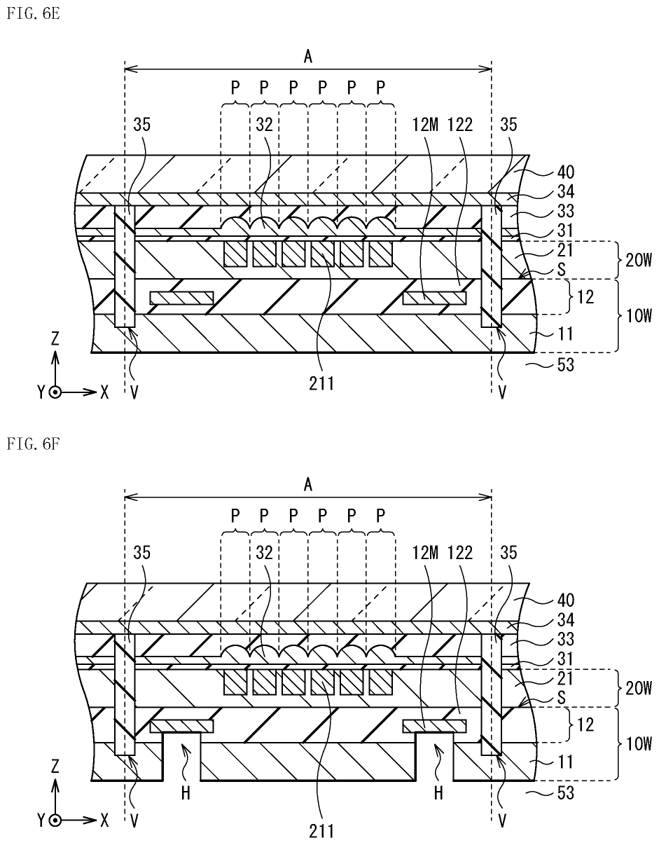

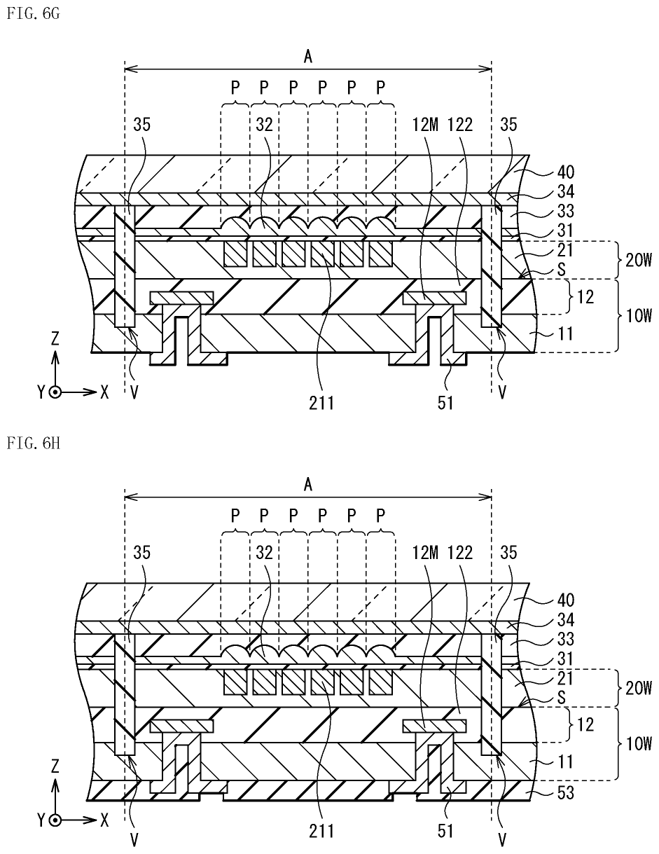

The cut portion C is provided, for example, to extend from the planarization film 33 in a stacking direction of the imaging device 1 (Z-axis direction). The cut portion C is provided in, for example, the planarization film 33, the insulating film 31, the sensor chip 20, and the logic chip 10. That is, the cut portion C extends through the planarization film 33, the insulating film 31, the semiconductor substrate 21, and the multilayered wiring layer 12. The cut portion C is formed by, for example, digging from the planarization film 33 to halfway in a thickness direction of the semiconductor substrate 11 (a groove V in FIG. 6B to be described later). A bottom surface of the cut portion C is provided, for example, inside the semiconductor substrate 11 of the logic chip 10. It suffices for the cut portion C to be provided over at least a thickness direction of the insulating film 31. For example, the cut portion C may be provided to extend from the insulating film 31 in the stacking direction of the imaging device 1. The cut portion C has, for example, a rectangular cross-sectional shape.

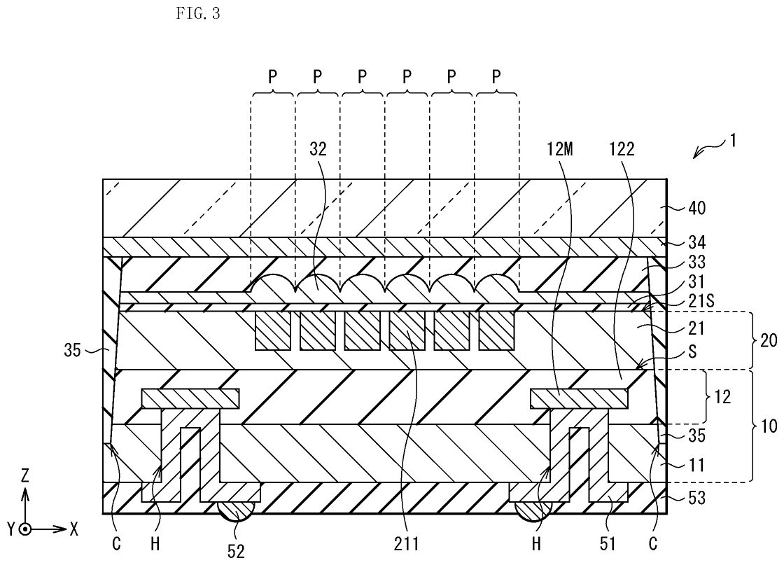

FIGS. 3 and 4 illustrate other examples of the cross-sectional configuration of the imaging device 1. As illustrated, the cut portion C of the imaging device 1 may have other cross-sectional shapes than rectangular. For example, as illustrated in FIG. 3, the cut portion C may have a tapered shape. Specifically, in the cut portion C, a width of the cut portion C is gradually reduced as goes from the planarization film 33 toward the semiconductor substrate 11. Alternatively, as illustrated in FIG. 4, the cut portion C may have a step. Specifically, in the cut portion C, the width of the cut portion C is stepwise reduced as goes from the planarization film 33 toward the semiconductor substrate 11.

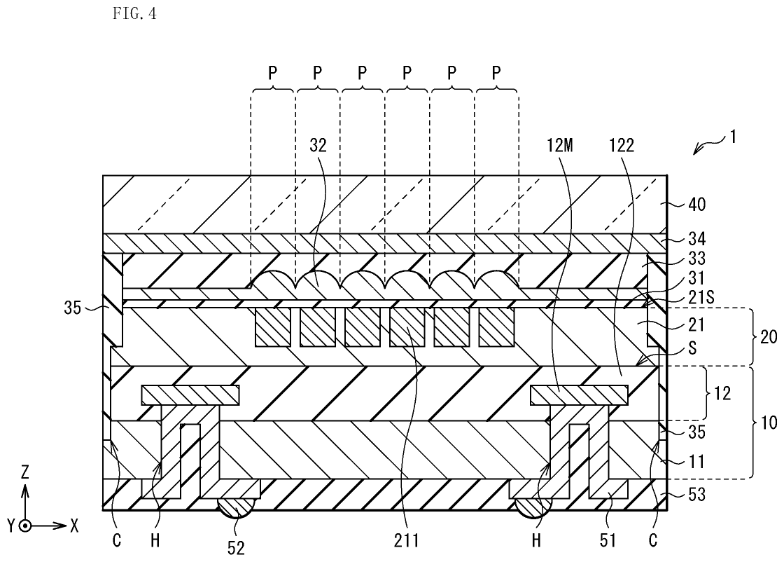

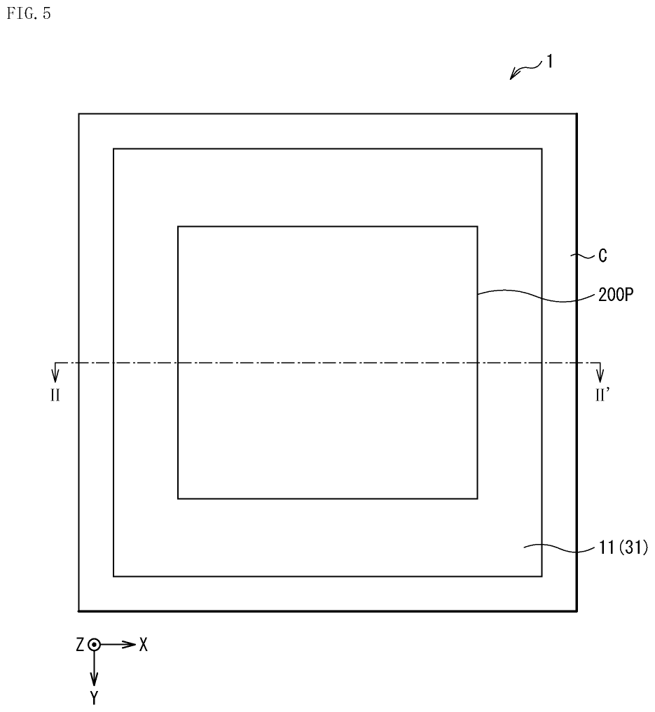

FIG. 5 illustrates an example of a planar shape of the cut portion C. A cross-sectional configuration along a line illustrated in FIG. 5 corresponds to FIG. 2. The cut portion C is provided, for example, on a periphery of the imaging device 1 (insulating film 31), and surrounds the pixel unit 200P in plan view. A planar shape of the cut portion C is, for example, a rectangle.

In the present embodiment, an implanted film 35 is implanted in the cut portion C. The implanted film 35 is different from the bonding member 34 and includes a material different from a material of the bonding member 34. As is described later in detail, this makes it possible to form the bonding member 34 thinner than in a case where the cut portion C is filled with the use of the bonding member 34.

The implanted film 35 is implanted, for example, in all in a depth direction of the cut portion C from the bottom surface of the cut portion C. A front surface of the planarization film 33 (surface on side on which the bonding member 34 is disposed) and a front surface of the implanted film 35 are substantially level with each other. The implanted film 35 includes, for example, an insulating material having low water permeability. The implanted film 35 includes, for example, an inorganic insulating material such as silicon nitride (SiN) and silicon oxynitride (SiON). The implanted film 35 may include an organic insulating material such as siloxane. As described above, providing the cut portion C on the periphery of the imaging device 1 and implanting the implanted film 35 having low water permeability in the cut portion C make it possible to suppress intrusion of moisture into the imaging device 1 through an end portion.

The protective member 40 is opposed to the sensor chip 20 with the insulating film 31, the microlens 32, and the planarization film 33 in between. The protective member 40 covers the light input surface 21S of the semiconductor substrate 21. The protective member 40 includes, for example, a transparent substrate such as a glass substrate. On a front surface of the protective member 40 (surface opposite to a surface on side on which the sensor chip 20 is disposed) or on a back surface of the protective member 40 (surface on the side on which the sensor chip 20 is disposed), for example, an IR (infrared) cut filter or the like may be provided. The protective member 40 is opposed to the logic chip 10 with the sensor chip 20 in between.

The bonding member 34 provided between the protective member 40 and the microlens 32 has, for example, a refractive index substantially the same as a refractive index of the protective member 40. For example, in a case where the protective member 40 is a glass substrate, the bonding member 34 includes preferably a material having a refractive index of about 1.51. The bonding member 34 is provided so as to fill space between the protective member 40 and the sensor chip 20. That is, the imaging device 1 has a so-called cavity-less structure. The bonding member 34 includes, for example, a light-transmitting resin material. A thickness of the bonding member 34 is, for example, 10 μm to 50 μm.

### (Method of Manufacturing Imaging Device 1)

Description is given next of a method of manufacturing the imaging device 1 with reference to FIGS. 6A to 6J.

First, as illustrated in FIG. 6A, a logic wafer 10W and a sensor wafer 20W are bonded to form the bonding surface S. The logic wafer 10W includes the semiconductor substrate 11 and the multilayered wiring layer 12. The sensor wafer 20W includes the semiconductor substrate 21 and the multilayered wiring layer (not illustrated). The PD 211 is formed in the semiconductor substrate 21. Moreover, on the light input surface 21S of the semiconductor substrate 21, the insulating film 31, the microlens 32, and the planarization film 33 are formed. Each of the logic wafer 10W and the sensor wafer 20W is provided with a plurality of chip regions A. In a post-process, the logic wafer 10W is singulated for each chip region A to form the logic chip 10, while the sensor wafer 20W is singulated for each chip region A to form the sensor chip 20.

Next, as illustrated in FIG. 6B, a groove V is formed in a scribe line between the adjacent chip regions A. In a post-process, the groove V contributes to formation of the cut portion C of the imaging device 1. The groove V is formed, for example, to extend from the front surface of the planarization film 33 through the insulating film 31, the sensor wafer 20W, and the multilayered wiring layer 12, and thereafter, is dug halfway in the thickness direction of the semiconductor substrate 11. For example, the groove V having a rectangular cross-sectional shape is formed.

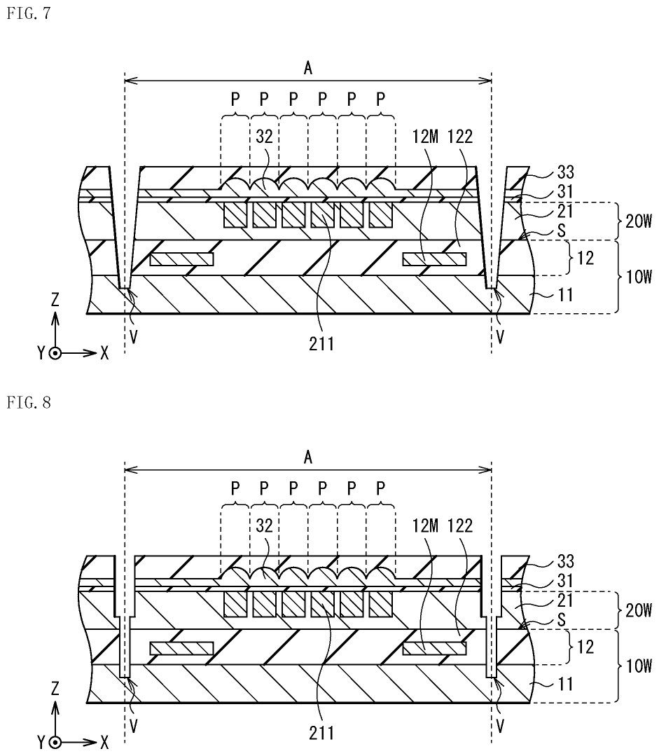

FIGS. 7 and 8 illustrate other examples of the process of forming the groove V. As illustrated in FIG. 7, the groove V may have a shape that decreases in width gradually as goes from the planarization film 33 toward the semiconductor substrate 11. That is, the groove V may be formed in a tapered shape. By forming the groove V illustrated in FIG. 7, the cut portion C illustrated in FIG. 3 is formed in a post-process. Alternatively, as illustrated in FIG. 8, the groove V may be formed in a shape that decreases in width stepwise as goes from the planarization film 33 toward the semiconductor substrate 11. By forming the groove V illustrated in FIG. 8, the cut portion C illustrated in FIG. 4 is formed in a post-process.

After the groove V is formed, as illustrated in FIG. 6C, the implanted film 35 is formed on the planarization film 33 so as to fill the groove V. The implanted film 35 is formed by, for example, forming a film of silicon nitride (SiN) with the use of a CVD (Chemical Vapor Deposition) method. At this occasion, in the groove V (FIGS. 7 and 8) that decreases in width as goes from the planarization film 33 toward the semiconductor substrate 11, it is possible to easily form the implanted film 35 in the bottom of the groove V, as compared to a case with the groove V of a constant width. In other words, by forming the groove V that decreases in width as goes from the planarization film 33 toward the semiconductor substrate 11, it is possible to enhance implanting property of the implanted film 35.

After the implanted film 35 is formed, as illustrated in FIG. 6D, the planarization film 33 and the implanted film 35 are planarized. Specifically, a surface on side on which the implanted film 35 is disposed is subjected to CMP (Chemical Mechanical Polishing), or is etched back, to form the front surface of the implanted film 35 to be level with the front surface of the planarization film 33.

Subsequently, as illustrated in FIG. 6E, the protective member 40 is bonded to the sensor wafer 20W with the planarization film 33 in between. The protective member 40 is bonded to the sensor wafer 20W using the bonding member 34. Although details are described later, here, the groove V is filled with the implanted film 35. Thus, the thickness of the bonding member 34 is reduced, as compared to the case where the bonding member 34 is implanted in the groove V.

After the protective member 40 is bonded to the sensor wafer 20W, as illustrated in FIG. 6F, the hole H is formed in the logic wafer 10W. For example, the hole H extends through the semiconductor substrate 11 and reaches the pad electrode 12M of the multilayered wiring layer 12.

After the hole H is formed, as illustrated in FIG. 6G, the rewiring 51 is formed. The rewiring 51 is electrically coupled to the pad electrode 12M. The rewiring 51 is formed, for example, as follows. First, a film of resist material is formed on the other of the main surfaces of the semiconductor substrate 11, and thereafter, an opening is formed in a selective region of the resist film. The opening is formed in the vicinity of the hole H. Next, using the resist film with the opening as a mask, a copper (Cu) film is formed by an electrolytic plating method. In this way, it is possible to form the rewiring 51 in the selective region in the vicinity of the hole H.

After the rewiring 51 is formed, as illustrated in FIG. 6H, a protective resin layer 53 is formed to cover the rewiring 51. An opening is formed in the protective resin layer 53. The opening is provided for coupling the solder bump 52 to the rewiring 51. After the protective resin layer 53 is formed, the solder bump 52 is formed (see FIG. 2). For example, it is possible to form the solder bump 52 by providing a ball-shaped solder material in the opening of the protective resin layer 53, and thereafter, subjecting the solder material to a heat treatment to form the solder material into a bump shape. Thereafter, dicing is performed along the scribe line. Thus, singulation is made for each chip region A, and the imaging device 1 is formed.

In the method of manufacturing the imaging device 1, the groove V is formed in the scribe line. This leads to relaxation of stress to be applied to interfaces between films of the imaging device 1 during singulation. Hence, it is possible to suppress the films from peeling off and cracking. Furthermore, it is possible to suppress intrusion of moisture into the imaging device 1 caused by the peeling off and cracking of the films. In addition, here, the implanted film 35 having low water permeability is implanted in the groove V. This leads to more effective suppression of intrusion of moisture into the imaging device 1.

### (Workings and Effects of Imaging Device 1)

In the imaging device 1 of the present embodiment, the implanted film 35 is implanted in the cut portion C. This leads to reduction in the thickness of the bonding member 34, as compared to the case where the bonding member 34 is implanted in the cut portion C. In the following, such workings and effects are described by giving a comparative example.

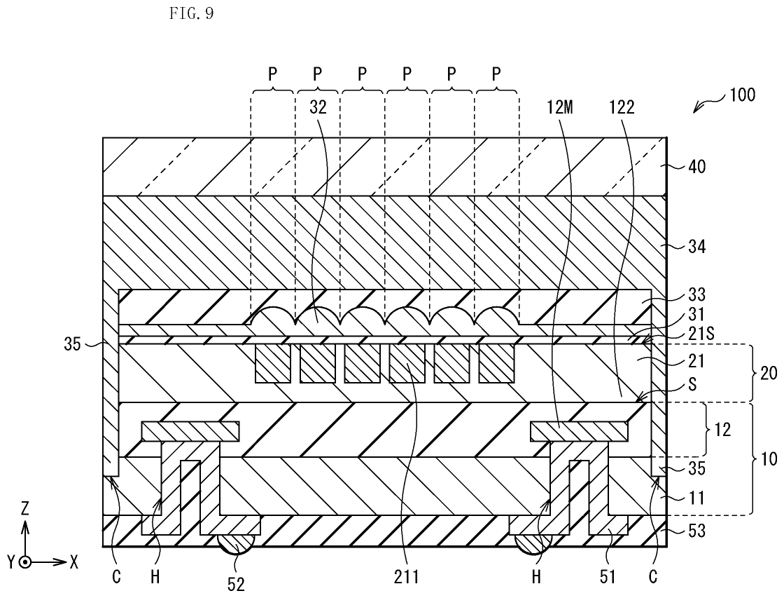

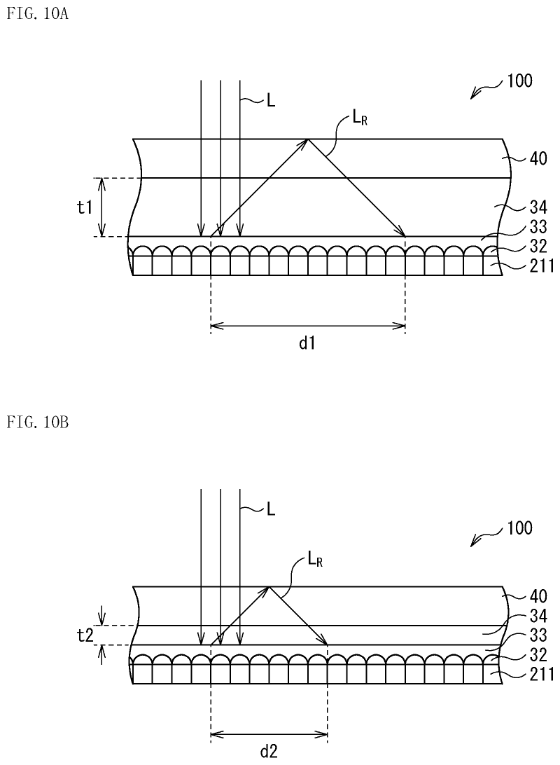

FIG. 9 illustrates a schematic cross-sectional configuration of a main portion of an imaging device (imaging device 100) according to the comparative example. The imaging device 100 includes the logic chip 10, the sensor chip 20, and the protective member 40. Between the protective member 40 and the sensor chip 20, the insulating film 31, the microlens 32, the planarization film 33, and the bonding member 34 are provided in this order from the side on which the sensor chip 20 is disposed. On the periphery of the imaging device 100, the cut portion C is provided from the planarization film 33 to the semiconductor substrate 11. In the imaging device 100, the bonding member 34 is implanted in the cut portion C. In this regard, the imaging device 100 is different from the imaging device 1.

In such an imaging device 100, at the time of manufacture, the groove V (see FIG. 6B) is filled with the bonding member 34. This makes it difficult to reduce the thickness of the bonding member 34. In the imaging device 100, for example, the thickness of the bonding member 34 is larger than 50 μm. The thickness of the bonding member 34 of the imaging device 100 is, for example, greater than 50 μm and smaller than or equal to 200 μm. In a case with the bonding member 34 having a great thickness, spread of light reflected from between the sensor chip 20 and the protective member 40 becomes greater. This causes ring-shaped flare to be easily recognized.

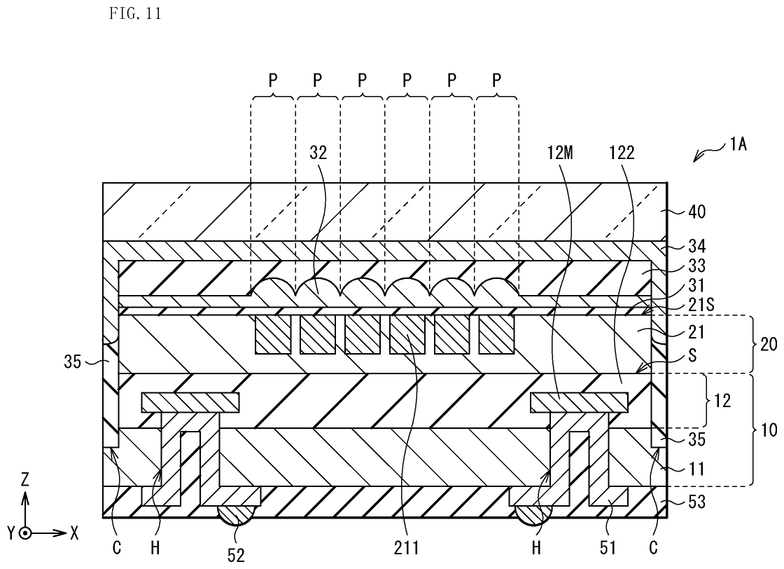

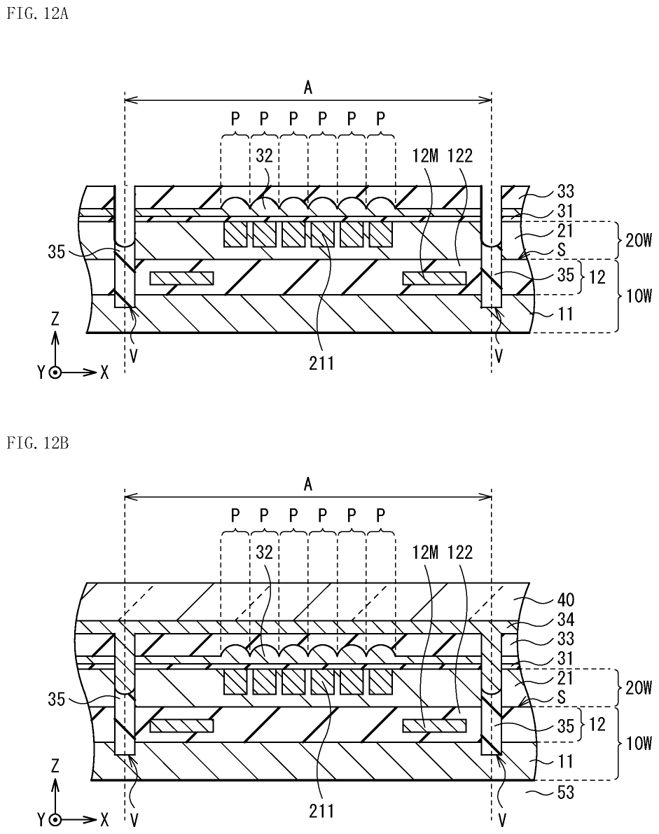

Description is given of relation between the thickness of the bonding member 34 and generation of flare, with reference to FIGS. 10A and 10B. Reflected light L_{R} illustrated in FIGS. 10A and 10B is derived from light L reflected from between the sensor chip 20 and the protective member 40 on the travel from a light source toward the sensor chip 20. FIG. 10A illustrates the reflected light L_{R} of the imaging device 100, and FIG. 10B illustrates the reflected light L_{R} of the imaging device 1. The imaging device 100 includes the bonding member 34 having a thickness t1, while the imaging device 1 includes the bonding member 34 having a thickness t2. The thickness t1 is greater than the thickness t2 (t1>t2).

In the imaging devices 1 and 100 of the cavity-less structure, the space between the protective member 40 and the sensor chip 20 is filled with the bonding member 34 having the refractive index comparable to the refractive index of the protective member 40. Accordingly, the light L is reflected from a front surface of the sensor chip 20 and enters the protective member 40 at an angle equal to or greater than a critical angle, causing total reflection. The reflected light L_{R} enters the pixel unit 200P (FIG. 1). Reducing a distance from a position where the light L directly enters the pixel unit 200P to a position where the reflected light L_{R} enters the pixel unit 200P (distances d1 and d2 described later) suppresses flare from being recognized. It is to be noted that in an imaging device of a cavity structure, such entrance of the reflected light to the pixel unit is less likely to occur.

In the imaging device 100, by reducing the thickness of the protective member 40, it is possible to reduce, to some extent, the distance d1 from the position where the light L directly enters the pixel unit 200P to the position where the reflected light L_{R} enters the pixel unit 200P. However, because the thickness t1 of the bonding member 34 is large, it is difficult to sufficiently reduce the distance d1 (FIG. 10A). In contrast, in the imaging device 1, it is possible to easily reduce the thickness t2 of the bonding member 34 (FIG. 10B) in addition to the thickness of the protective member 40. Hence, it is possible to sufficiently reduce the distance d2 (d1>d2) from the position where the light L directly enters the pixel unit 200P to the position where the reflected light L_{R} enters the pixel unit 200P. This leads to reduction in visibility of flare.

As described above, in the imaging device 1 according to the present embodiment, the implanted film 35 is implanted in the cut portion C. Accordingly, it is possible to reduce the thickness (thickness t2) of the bonding member 34 as compared to the case where the cut portion C is filled with the use of the bonding member 34. This makes it possible to reduce the spread of the light (reflected light L_{R}) reflected from between the semiconductor substrate 21 (sensor chip 20) and the protective member 40. Hence, it is possible to suppress a decrease in image quality caused by flare, etc.

Moreover, in the imaging device 1, the implanted film 35 is implanted in all in the depth direction of the cut portion C. Hence, it is possible to reduce the thickness t2 of the bonding member 34 more effectively than in a case where the implanted film 35 is implanted in a portion in the depth direction of the cut portion C (for example, an imaging device 1A in FIG. 11 described later).

Furthermore, in the imaging device 1, a chip end face is covered with the implanted film 35 having low water permeability. Hence, it is possible to suppress intrusion of moisture through the end face.

Description is given below of modification examples of the forgoing first embodiment and other embodiments. However, in the following description, the same constituent elements as those of the forgoing embodiment are denoted by the same reference numerals, and description thereof is omitted as appropriate.

### Modification Example 1

FIG. 11 illustrates a schematic cross-sectional configuration of a main portion of an imaging device (imaging device 1A) according to a modification example 1 of the forgoing first embodiment. Here, the implanted film 35 is implanted in a portion in the depth direction of the cut portion C. Except for this point, the imaging device 1A according to the modification example 1 has a similar configuration to the imaging device 1 of the forgoing first embodiment, and has similar workings and effects.

The cut portion C is provided in, for example, the planarization film 33, the insulating film 31, the sensor chip 20, and the logic chip 10. The bottom surface of the cut portion C is provided, for example, halfway in the thickness direction of the semiconductor substrate 11. The cross-sectional shape of the cut portion C is, for example, rectangular (FIG. 11). The cut portion C may have other cross-sectional shapes than rectangular (see FIGS. 3 and 4). A height of the implanted film 35 (dimension in the Z-axis direction) is smaller than the depth of the cut portion C, and the front surface of the implanted film 35 is provided, for example, inside the semiconductor substrate 21. That is, in the Z-axis direction, the front surface of the implanted film 35 is disposed at a position closer to the bottom surface of the cut portion C than the front surface of the planarization film 33 is. In the cut portion C, the implanted film 35 and the bonding member 34 are implanted in this order from side on which the bottom surface of the cut portion C is disposed.

Such an imaging device 1A can be manufactured, for example, as follows (FIGS. 12A and 12B).

First, in a similar manner to as described in the forgoing first embodiment, the groove V is formed by digging from the planarization film 33 to the semiconductor substrate 11 (see FIG. 6B). For example, the groove V having the rectangular cross-sectional shape is formed. In a similar manner to as described in the forgoing first embodiment, the groove V may be formed that decreases in width gradually or stepwise as goes from the insulating film 31 toward the semiconductor substrate 11 (FIGS. 7 and 8).

Next, as illustrated in FIG. 12A, the implanted film 35 is formed so as to fill a portion in the depth direction of the groove V. The implanted film 35 is formed by, for example, forming a film of an organic insulating material such as a resin using a coating method. Examples of the organic insulating material include siloxane and epoxy resin, etc.

After the implanted film 35 is formed, as illustrated in FIG. 12B, the protective member 40 is bonded to the sensor wafer 20W. The protective member 40 is bonded using the bonding member 34. Here, a portion in the depth direction of the groove V is filled with the implanted film 35. Accordingly, the thickness of the bonding member 34 is reduced, as compared to the case where the bonding member 34 is implanted in all in the depth direction of the groove V.

After the protective member 40 is bonded to the sensor wafer 20W, the imaging device 1A can be manufactured in a similar manner to as described in the forgoing first embodiment.

In the imaging device 1A according to the present modification example, the implanted film 35 is implanted in a portion in the depth direction of the cut portion C. Accordingly, the thickness of the bonding member 34 is reduced, as compared to the case where the bonding member 34 is implanted in all in the depth direction of the cut portion C. Hence, it is possible to suppress a decrease in image quality caused by flare, etc. Moreover, in the imaging device 1A, it suffices to form the implanted film 35 in a portion in the depth direction of the groove V (FIG. 12A). This renders unnecessary the planarization process of the implanted film 35 and the planarization film 33 (for example, the process in FIG. 6D of the imaging device 1). Accordingly, it is possible to reduce manufacturing costs caused by the planarization process. In addition, it is possible to suppress deterioration of the pixel unit 200P caused by the planarization process. Hence, it is possible to suppress, for example, generation of noise, leading to further enhancement in image quality.

### Modification Example 2

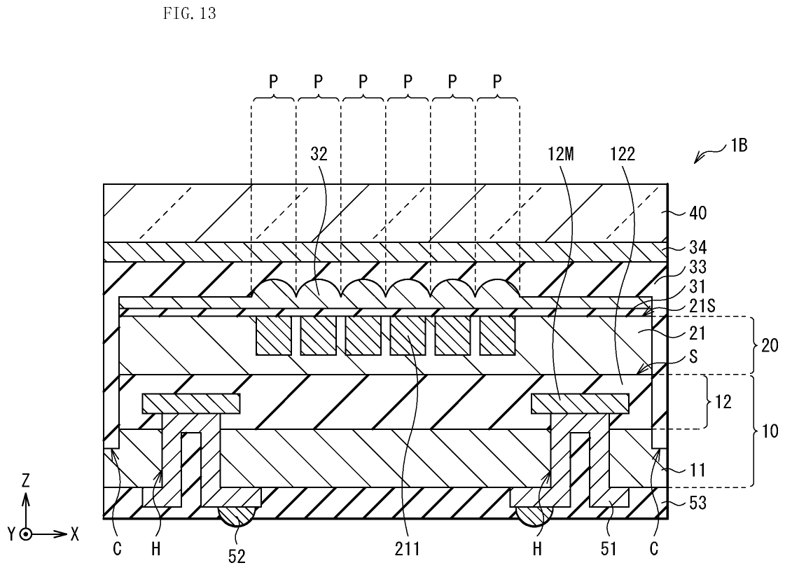

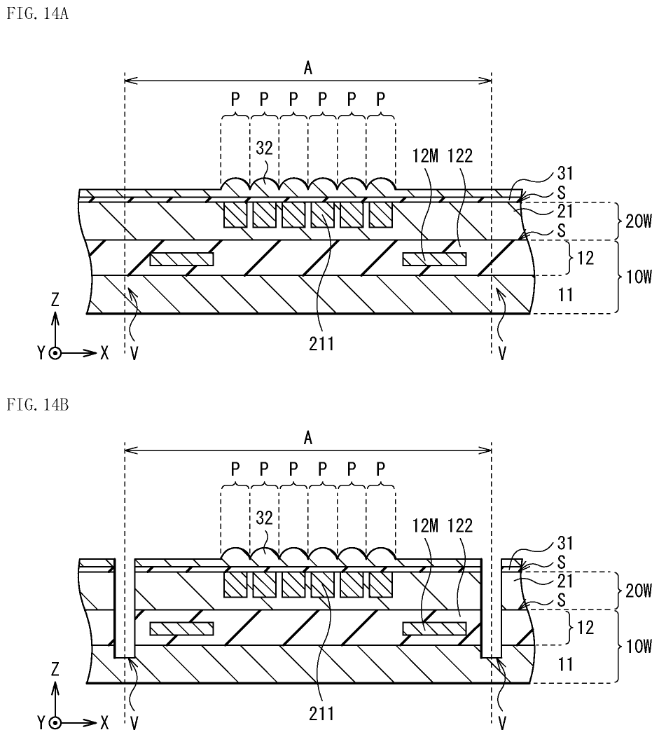

FIG. 13 schematically illustrates a cross-sectional configuration of a main portion of an imaging device (imaging device 1B) according to a modification example 2 of the forgoing first embodiment. Here, the planarization film 33 is implanted in the cut portion C. Except for this point, the imaging device 1B according to the modification example 2 has a similar configuration to the imaging device 1 of the forgoing first embodiment, and has similar workings and effects.

The planarization film 33 covers the microlens 32 and is implanted in, for example, all in the depth direction of the cut portion C. The cross-sectional shape of the cut portion C is, for example, rectangular (FIG. 13). The cut portion C may have other cross-sectional shapes than rectangular (see FIGS. 3 and 4). The planarization film 33 is continuously provided, for example, from over the microlens 32 to an inside of the cut portion C. That is, the planarization film 33 has a function as an implanted film in the cut portion C, together with a function of planarizing the light input surface 21S of the semiconductor substrate 21. In other words, a material of the planarization film 33 is the same as a material of the implanted film. Here, the planarization film 33 corresponds to one specific example of the implanted film of the present disclosure.

A refractive index of the material of the planarization film 33 is preferably lower than the refractive index of the material of the microlens 32. This causes light entering the microlens 32 to be efficiently collected on the PD 211. For example, in a case where the material of the microlens 32 is a silicon nitride film (refractive index 1.8), siloxane (refractive index 1.4) can be used as the material of the planarization film 33.

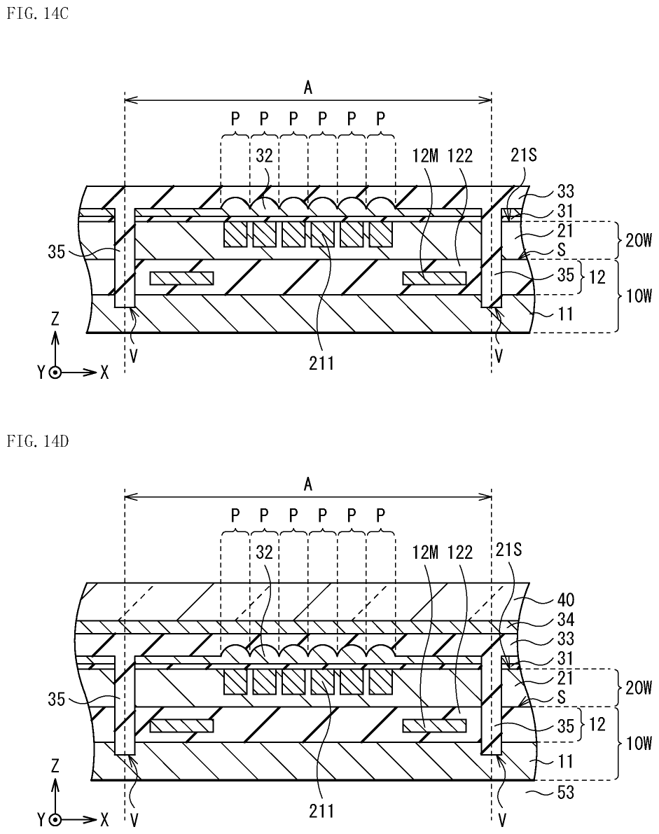

Such an imaging device 1B can be manufactured, for example, as follows (FIGS. 14A to 14D).

First, as illustrated in FIG. 14A, the logic wafer 10W and the sensor wafer 20W are bonded to form the bonding surface S. The logic wafer 10W includes the semiconductor substrate 11 and the multilayered wiring layer 12. The sensor wafer 20W includes the semiconductor substrate 21 and the multilayered wiring layer (not illustrated). The PD 211 is formed on the semiconductor substrate 21. Moreover, on the light input surface 21S of the semiconductor substrate 21, the insulating film 31 and the microlens 32 are formed.

Next, as illustrated in FIG. 14B, the groove V is formed in the scribe line between the adjacent chip regions A. The groove V is formed, for example, to extend from a front surface of the insulating film 31 through the sensor wafer 20W and the multilayered wiring layer 12, and thereafter, is dug halfway in the thickness direction of the semiconductor substrate 11. For example, the groove V having the rectangular cross-sectional shape is formed. In the similar manner to as described in the forgoing first embodiment, the groove V may be formed that has the shape that decreases in width gradually or stepwise as goes from the insulating film 31 toward the semiconductor substrate 11 (see FIGS. 7 and 8).

After the groove V is formed, as illustrated in FIG. 14C, the planarization film 33 is formed on the microlens 32 to fill the groove V. The planarization film 33 is formed by, for example, forming a film of siloxane using a CVD method or a coating method.

After the planarization film 33 is formed, as illustrated in FIG. 14D, the protective member 40 is bonded to the sensor wafer 20W with the planarization film 33 in between. The protective member 40 is bonded to the sensor wafer 20W using the bonding member 34. Here, the groove V is filled with the planarization film 33. Accordingly, the thickness of the bonding member 34 is reduced, as compared to the case where the bonding member 34 is implanted in the groove V. Before the protective member 40 is bonded to the sensor wafer 20W, a process may be provided in which the planarization film 33 is subjected to CMP or is etched back to adjust the thickness of the planarization film 33.

After the protective member 40 is bonded to the sensor wafer 20W, the imaging device 1B can be manufactured in the similar manner to as described in the forgoing first embodiment.

In the imaging device 1B according to the present modification example, the planarization film 33 is implanted in the cut portion C. Accordingly, the thickness of the bonding member 34 is reduced, as compared to the case where the bonding member 34 is implanted in the cut portion C. Hence, it is possible to suppress a decrease in image quality caused by flare, etc. Moreover, in the imaging device 1B, the planarization film 33 covers the microlens 32 and is implanted in the groove V. This makes it possible to reduce the number of processes, as compared to a case where the process of forming the planarization film 33 and the process of forming the implanted film in the groove V (see FIG. 6C) are separately performed. Hence, it is possible to reduce the manufacturing costs.

### Second Embodiment

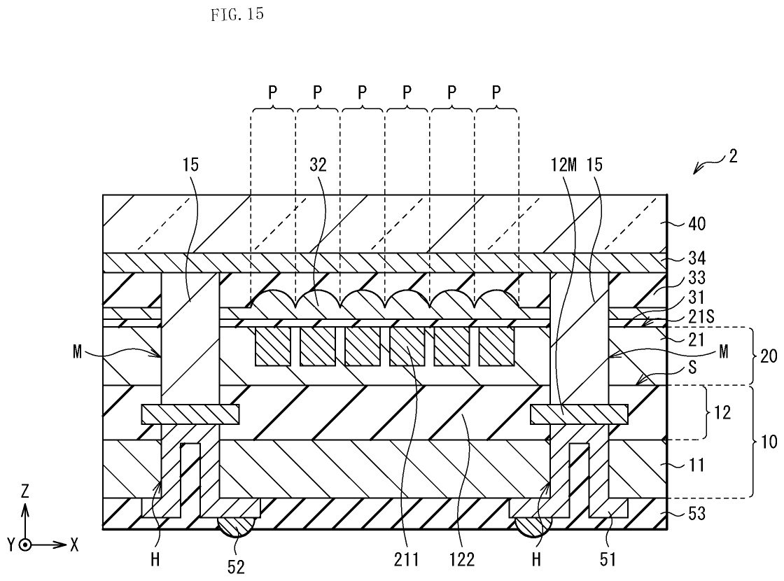

FIG. 15 schematically illustrates a cross-sectional configuration of a main portion of an imaging device (imaging device 2) according to a second embodiment of the present disclosure. The imaging device 2 includes a hole portion M that extends through the planarization film 33, the insulating film 31, and the sensor chip 20 to reach the pad electrode 12M. In the hole portion M, an electrically conductive implanted film (implanted film 15) is implanted. That is, the hole portion M is provided instead of the cut portion C (FIG. 1) of the forgoing first embodiment. Except for this point, the imaging device 1 according to the second embodiment has a similar configuration to the imaging device 1 of the forgoing first embodiment, and similar workings and effects.

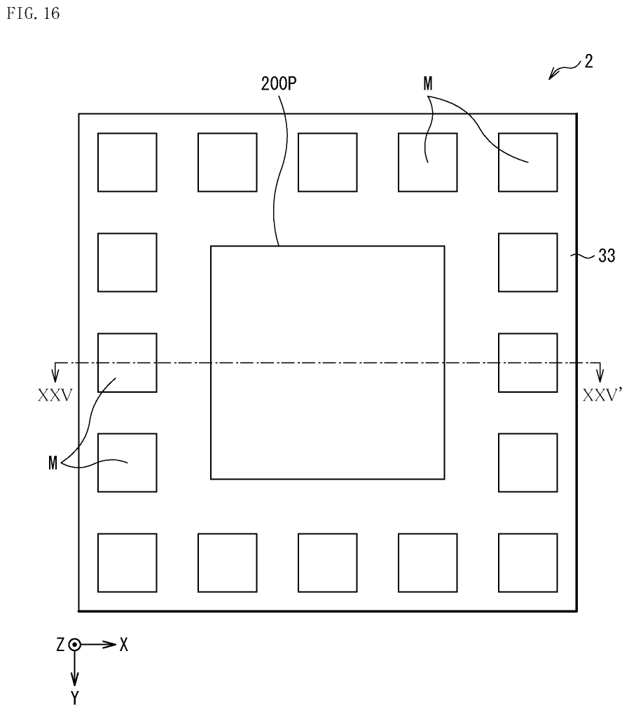

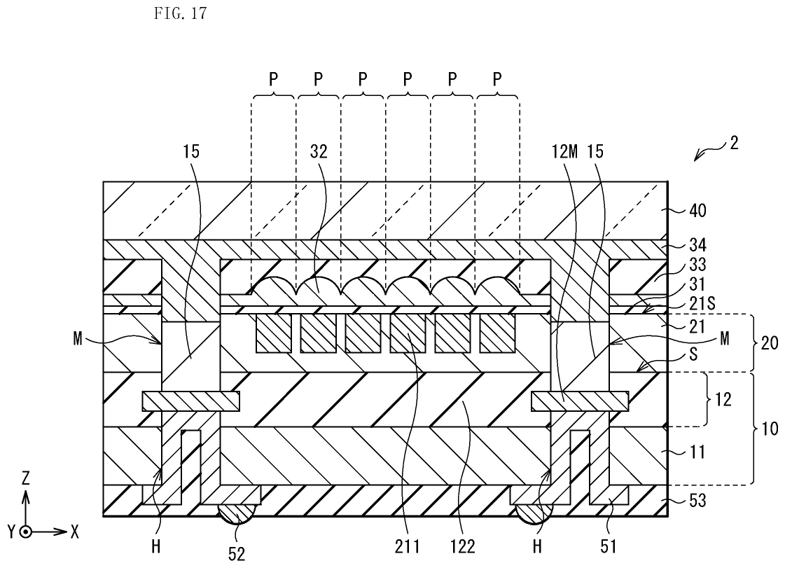

FIG. 16 schematically illustrates an example of a plan configuration of the hole portion M together with the planarization film 33. A cross-sectional configuration along a line XXV-XXV′ illustrated in FIG. 16 corresponds to FIG. 15. The imaging device 2 has a plurality of the hole portions M outside the pixel unit 200P. The plurality of the hole portions M is disposed to be spaced away from one another. Each of the plurality of the hole portions M has, for example, a rectangular planar shape. For example, the plurality of the hole portions M is disposed to surround the pixel unit 200P in plan view. Each of the plurality of the hole portions M may have other planar shapes than rectangular, for example, circular, etc.

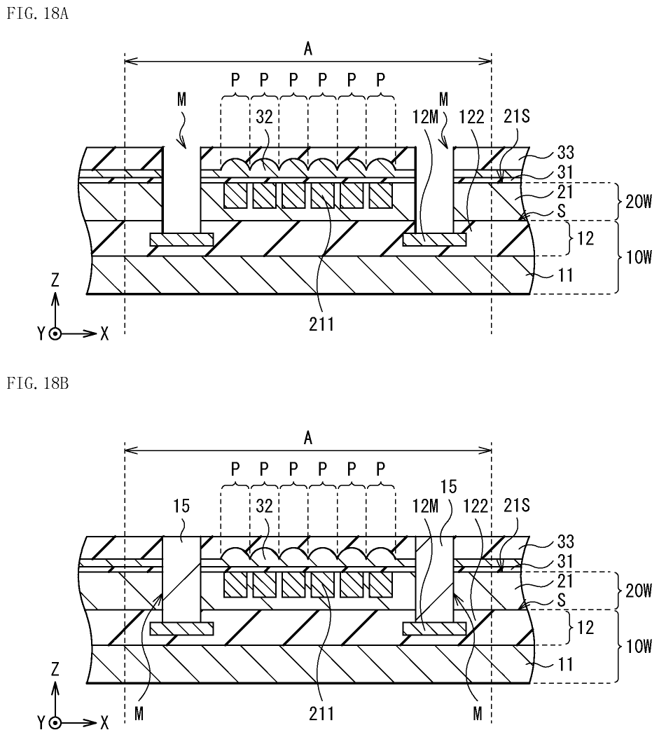

Although details are described later, the hole portion M and the implanted film 15 are provided for performing, for example, an inspection using a needle in a wafer state during a manufacturing process of the imaging device 2. The hole portion M is provided in, for example, the planarization film 33, the insulating film 31, the sensor chip 20, and the multilayered wiring layer 12 (logic chip 10). The hole portion M is formed by, for example, digging from the planarization film 33 to the pad electrode 12M of the multilayered wiring layer 12 (hole portion M in FIG. 18A described later). At a bottom surface of the hole portion M, the pad electrode 12M is exposed. The hole portion M has, for example, a rectangular cross-sectional shape. The hole portion M may have other cross-sectional shapes than rectangular. For example, a width of the hole portion M may be reduced gradually or stepwise as goes from the planarization film 33 toward the multilayered wiring layer 12 (see FIGS. 3 and 4). The hole portion M is disposed, for example, at a position opposed to the hole H.

The implanted film 15 is implanted, for example, in all in the depth direction of the hole portion M. The front surface of the planarization film 33 (surface on the side on which the bonding member 34 is disposed) and a front surface of the implanted film 15 are substantially level with each other. The implanted film 15 includes, for example, an electrically conductive metal material. Examples of the electrically conductive metal material include aluminum (Al), copper (Cu), and nickel (Ni), without limitation. The implanted film 15 is electrically coupled to the pad electrode 12M. For example, a wiring coupled to the pad electrode 12 may be provided, and the implanted film 15 may be coupled to the wiring. At this occasion, the hole portion M may be disposed at a position deviated from the position opposed to the hole H.

FIG. 17 illustrates another example of the cross-sectional configuration of the main portion of the imaging device 2. As illustrated, the implanted film 15 may be implanted in a portion in the depth direction of the hole portion M. At this occasion, a height of the implanted film 15 is smaller than a depth of the hole portion M, and the front surface of the implanted film 15 is provided, for example, inside the semiconductor substrate 21. That is, in the Z-axis direction, the front surface of the implanted film 15 is disposed at a position closer to the bottom surface of the hole portion M (pad electrode 12M) than the front surface of the planarization film 33 is. In the hole portion M, the implanted film 15 and the bonding member 34 are implanted in this order from side on which the bottom surface is disposed.

Such an imaging device 2 can be manufactured, for example, as follows (FIGS. 18A and 18B).

First, in the similar manner to as described in the forgoing first embodiment, the logic wafer 10W and the sensor wafer 20W are bonded to form the bonding surface S. The logic wafer 10W includes the semiconductor substrate 11 and the multilayered wiring layer 12. The sensor wafer 20W includes the semiconductor substrate 21 and the multilayered wiring layer (not illustrated). The PD 211 is formed on the semiconductor substrate 21. Moreover, on the light input surface 21S of the semiconductor substrate 21, the insulating film 31 and the microlens 32 are formed (FIG. 6A).

Next, as illustrated in FIG. 18A, the plurality of the hole portions M is formed that extends from the planarization film 33 to reach the pad electrode 12M. Subsequently, as illustrated in FIG. 18B, the implanted film 15 is formed to be selectively implanted in the hole portion M. The implanted film 15 is formed, for example, by forming a film of a metal material using a plating method. Thus, the implanted film 15 electrically coupled to the pad electrode 12M is formed. For example, the implanted film 15 is formed to fill all in the depth direction of the hole portion M. The implanted film 15 may be formed to fill a portion in the depth direction of the hole portion M.

After the implanted film 15 is formed, for example, a probe needle is applied to the front surface of the implanted film 15 to perform the inspection in the wafer state. This makes it possible to detect, for example, a malfunction.

After the implanted film 15 is formed, the protective member 40 is bonded to the sensor wafer 20W. The protective member 40 is bonded using the bonding member 34 (see FIG. 6E). Here, the hole portion M is filled with the implanted film 15. Accordingly, the thickness of the bonding member 34 is reduced, as compared to the case where the bonding member 34 is implanted in the hole portion M.

After the protective member 40 is bonded to the sensor wafer 20W, the imaging device 2 can be manufactured in the similar manner to as described in the forgoing first embodiment.

In the imaging device 2 according to the present embodiment, the implanted film 15 is implanted in the hole portion M. Accordingly, the thickness of the bonding member 34 is reduced, as compared to the case where the bonding member 34 is implanted in the hole portion M. Hence, it is possible to suppress a decrease in image quality caused by flare, etc. Moreover, in the imaging device 2, it is possible to fill the hole portion M with the implanted film 15 including a metal material. This makes it easier to maintain strength to form the hole H at the position opposed to the hole portion M. Furthermore, in the case where the inspection is made in the wafer state, a needle is applied to the front surface of the implanted film 15. Accordingly, the thick implanted film 15 alleviates an impact caused by abutment of the needle, making it possible to suppress deterioration of each part caused by the abutment of the needle.

### Modification Example 3

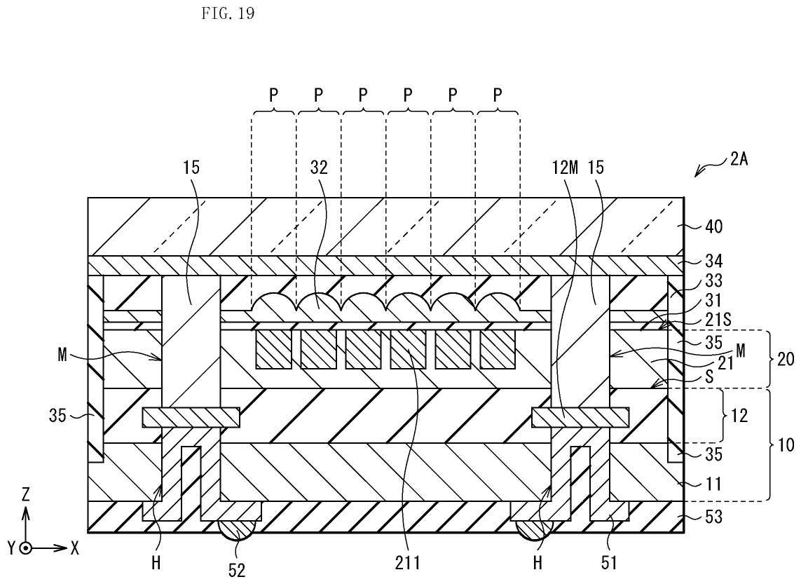

FIG. 19 schematically illustrates a cross-sectional configuration of a main portion of an imaging device (imaging device 2A) according to a modification example 4 of the forgoing second embodiment. The imaging device 2A includes the hole portion M and the cut portion C outside the pixel unit 200P. The implanted film 35 is implanted in the cut portion C. That is, the imaging device 2A includes the hole portion M in which the implanted film 15 is implanted, and the cut portion C in which the implanted film 35 is implanted. Except for this point, the imaging device 2A according to the modification example 3 has a similar configuration to the imaging device 2 of the forgoing second embodiment, and similar workings and effects.

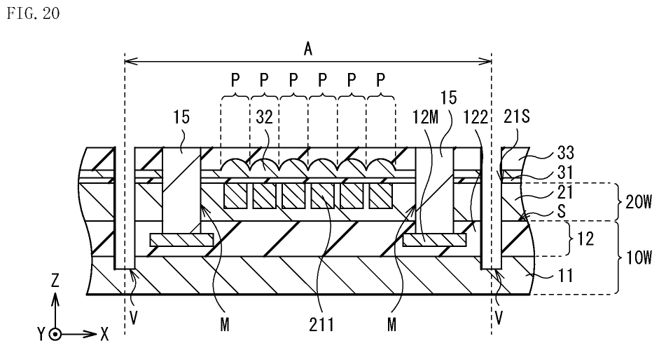

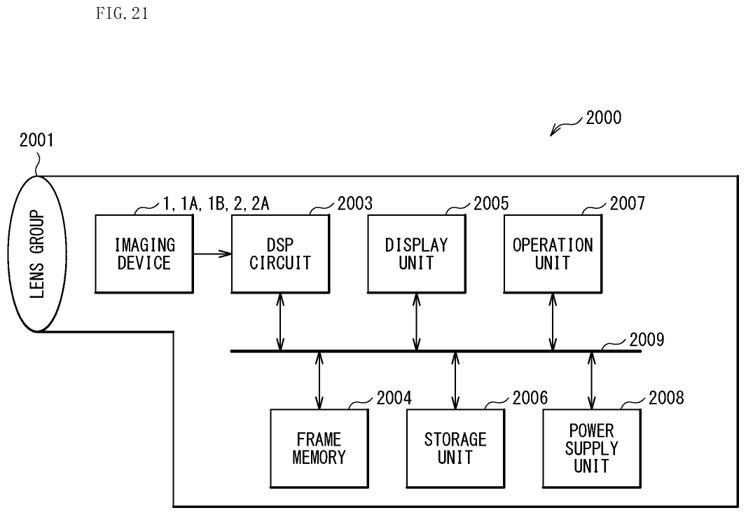

The cut portion C is formed, for example, by digging from the planarization film 33 to halfway in the thickness direction of the semiconductor substrate 11 (groove V in FIG. 20 described later), in the similar manner to as described in the forgoing first embodiment. The cut portion C is provided on the periphery of the imaging device 2. The cross-sectional shape of the cut portion C is, for example, rectangular (FIG. 19). The cut portion C may have other cross-sectional shapes than rectangular (see FIGS. 3 and 4). The implanted film 35 implanted in the cut portion C includes, for example, an insulating material having low water permeability, similarly to as described in the forgoing first embodiment.

Such an imaging device 2A can be manufactured, for example, as follows (FIG. 20).

First, in the similar manner to as described in the forgoing second embodiment, the implanted film 15 and thereunder are formed (FIG. 18B). Next, as illustrated in FIG. 20, the groove V is formed in the scribe line between the adjacent chip regions A. The groove V is formed, for example, to extend from the front surface of the planarization film 33 through the insulating film 31, the sensor wafer 20W, and the multilayered wiring layer 12, and thereafter, is dug halfway in the thickness direction of the semiconductor substrate 11. After the groove V is formed, the implanted film 35 is formed (see FIG. 6C).

After the implanted film 35 is formed, the imaging device 2A can be manufactured in the similar manner to as described in the forgoing first embodiment.

In the imaging device 2A according to the present modification example, the implanted film 15 is implanted in the hole portion M and the implanted film 35 is implanted in the cut portion C. Accordingly, the thickness of the bonding member 34 is reduced, as compared to the case where the bonding member 34 is implanted in the hole portion M and the cut portion C.

### Application Example

The present technology is not limited to the application to imaging devices, but applicable to electronic apparatuses in general that use imaging devices as image capturing units (photoelectric conversion units). Examples include an imaging device of, for example, a digital still camera and a video camera, a mobile terminal device having an imaging function such as a mobile phone, and a photocopier that uses an imaging device as an image reading unit. It is to be noted that imaging devices sometimes assume a camera module, i.e., a modular form to be mounted on an electronic apparatus.

FIG. 21 is a block diagram illustrating a configuration example of an electronic apparatus 2000 as an example of an electronic apparatus of the present disclosure. The electronic apparatus 2000 is, for example, a camera module for a mobile apparatus such as a digital still camera, a video camera, and a mobile phone. As illustrated in FIG. 21, the electronic apparatus 2000 of the present disclosure includes, for example, an optical unit including a lens group 2001, etc., the imaging device 1, 1A, 1B, 2, or 2A (hereinbelow correctively referred to as the imaging device 1), a DSP circuit 2003 as a camera signal processor, a frame memory 2004, a display unit 2005, a storage unit 2006, an operation unit 2007, and a power supply unit 2008.

Moreover, a configuration is provided in which the DSP circuit 2003, the frame memory 2004, the display unit 2005, the storage unit 2006, the operation unit 2007, and the power supply unit 2008 are coupled to one another through a bus line 2009.

The lens group 2001 takes in entering light (image light) from a subject and forms am image on an imaging plane of the imaging device 1. The imaging device 1 converts an amount of light of the entering light with which the lens group 2001 forms the image on the imaging plane, into an electric signal for each pixel. The imaging device 1 outputs the electric signal as a pixel signal.

The display unit 2005 includes, for example, a panel display unit such as a liquid crystal display unit or an organic EL (Electro Luminescence) display unit, and displays a moving image or a still image captured by the imaging device 1. The storage unit 2006 records the moving image or the still image captured by the solid-state imaging element 2002, in a recording medium such as a DVD (Digital Versatile Disk).

The operation unit 2007 gives an operation instruction about various kinds of functions of the imaging device in accordance with an operation by a user. The power supply unit 2008 supplies various kinds of power serving as operation power for the DSP circuit 2003, the frame memory 2004, the display unit 2005, the storage unit 2006, and the operation unit 2007, to these targets of supply as appropriate.

### <Practical Application Examples to In-Vivo Information Acquisition System>

Furthermore, the technology according to the present disclosure (the present technology) is applicable to various products. For example, the technology according to the present disclosure may be applied to an endoscopic surgery system.

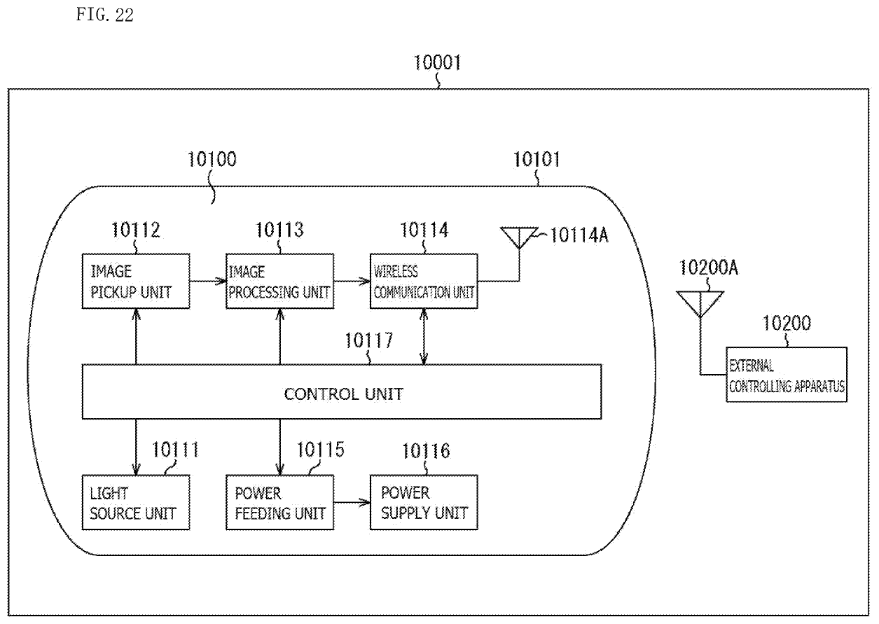

FIG. 22 is a block diagram depicting an example of a schematic configuration of an in-vivo information acquisition system of a patient using a capsule type endoscope, to which the technology according to an embodiment of the present disclosure (present technology) can be applied.

The in-vivo information acquisition system 10001 includes a capsule type endoscope 10100 and an external controlling apparatus 10200.

The capsule type endoscope 10100 is swallowed by a patient at the time of inspection. The capsule type endoscope 10100 has an image pickup function and a wireless communication function and successively picks up an image of the inside of an organ such as the stomach or an intestine (hereinafter referred to as in-vivo image) at predetermined intervals while it moves inside of the organ by peristaltic motion for a period of time until it is naturally discharged from the patient. Then, the capsule type endoscope 10100 successively transmits information of the in-vivo image to the external controlling apparatus 10200 outside the body by wireless transmission.

The external controlling apparatus 10200 integrally controls operation of the in-vivo information acquisition system 10001. Further, the external controlling apparatus 10200 receives information of an in-vivo image transmitted thereto from the capsule type endoscope 10100 and generates image data for displaying the in-vivo image on a display apparatus (not depicted) on the basis of the received information of the in-vivo image.

In the in-vivo information acquisition system 10001, an in-vivo image imaged a state of the inside of the body of a patient can be acquired at any time in this manner for a period of time until the capsule type endoscope 10100 is discharged after it is swallowed.

A configuration and functions of the capsule type endoscope 10100 and the external controlling apparatus 10200 are described in more detail below.

The capsule type endoscope 10100 includes a housing 10101 of the capsule type, in which a light source unit 10111, an image pickup unit 10112, an image processing unit 10113, a wireless communication unit 10114, a power feeding unit 10115, a power supply unit 10116 and a control unit 10117 are accommodated.

The light source unit 10111 includes a light source such as, for example, a light emitting diode (LED) and irradiates light on an image pickup field-of-view of the image pickup unit 10112.

The image pickup unit 10112 includes an image pickup element and an optical system including a plurality of lenses provided at a preceding stage to the image pickup element. Reflected light (hereinafter referred to as observation light) of light irradiated on a body tissue which is an observation target is condensed by the optical system and introduced into the image pickup element. In the image pickup unit 10112, the incident observation light is photoelectrically converted by the image pickup element, by which an image signal corresponding to the observation light is generated. The image signal generated by the image pickup unit 10112 is provided to the image processing unit 10113.

The image processing unit 10113 includes a processor such as a central processing unit (CPU) or a graphics processing unit (GPU) and performs various signal processes for an image signal generated by the image pickup unit 10112. The image processing unit 10113 provides the image signal for which the signal processes have been performed thereby as RAW data to the wireless communication unit 10114.

The wireless communication unit 10114 performs a predetermined process such as a modulation process for the image signal for which the signal processes have been performed by the image processing unit 10113 and transmits the resulting image signal to the external controlling apparatus 10200 through an antenna 10114A. Further, the wireless communication unit 10114 receives a control signal relating to driving control of the capsule type endoscope 10100 from the external controlling apparatus 10200 through the antenna 10114A. The wireless communication unit 10114 provides the control signal received from the external controlling apparatus 10200 to the control unit 10117.

The power feeding unit 10115 includes an antenna coil for power reception, a power regeneration circuit for regenerating electric power from current generated in the antenna coil, a voltage booster circuit and so forth. The power feeding unit 10115 generates electric power using the principle of non-contact charging.

The power supply unit 10116 includes a secondary battery and stores electric power generated by the power feeding unit 10115. In FIG. 22, in order to avoid complicated illustration, an arrow mark indicative of a supply destination of electric power from the power supply unit 10116 and so forth are omitted. However, electric power stored in the power supply unit 10116 is supplied to and can be used to drive the light source unit 10111, the image pickup unit 10112, the image processing unit 10113, the wireless communication unit 10114 and the control unit 10117.

The control unit 10117 includes a processor such as a CPU and suitably controls driving of the light source unit 10111, the image pickup unit 10112, the image processing unit 10113, the wireless communication unit 10114 and the power feeding unit 10115 in accordance with a control signal transmitted thereto from the external controlling apparatus 10200.

The external controlling apparatus 10200 includes a processor such as a CPU or a GPU, a microcomputer, a control board or the like in which a processor and a storage element such as a memory are mixedly incorporated. The external controlling apparatus 10200 transmits a control signal to the control unit 10117 of the capsule type endoscope 10100 through an antenna 10200A to control operation of the capsule type endoscope 10100. In the capsule type endoscope 10100, an irradiation condition of light upon an observation target of the light source unit 10111 can be changed, for example, in accordance with a control signal from the external controlling apparatus 10200. Further, an image pickup condition (for example, a frame rate, an exposure value or the like of the image pickup unit 10112) can be changed in accordance with a control signal from the external controlling apparatus 10200. Further, the substance of processing by the image processing unit 10113 or a condition for transmitting an image signal from the wireless communication unit 10114 (for example, a transmission interval, a transmission image number or the like) may be changed in accordance with a control signal from the external controlling apparatus 10200.

Further, the external controlling apparatus 10200 performs various image processes for an image signal transmitted thereto from the capsule type endoscope 10100 to generate image data for displaying a picked up in-vivo image on the display apparatus. As the image processes, various signal processes can be performed such as, for example, a development process (demosaic process), an image quality improving process (bandwidth enhancement process, a super-resolution process, a noise reduction (NR) process and/or image stabilization process) and/or an enlargement process (electronic zooming process). The external controlling apparatus 10200 controls driving of the display apparatus to cause the display apparatus to display a picked up in-vivo image on the basis of generated image data. Alternatively, the external controlling apparatus 10200 may also control a recording apparatus (not depicted) to record generated image data or control a printing apparatus (not depicted) to output generated image data by printing.

In the forgoing, an example of the in-vivo information acquisition system is described to which the technology according to the present disclosure is applicable. The technology according to the present disclosure is applicable to, for example, the image pick up unit 10112 out of the configuration described above. This leads to enhancement in detection accuracy.

### <Practical Application Examples to Endoscopic Surgery System>

The technology according to the present disclosure (the present technology) is applicable to various products. For example, the technology according to the present disclosure may be applied to an endoscopic surgery system.

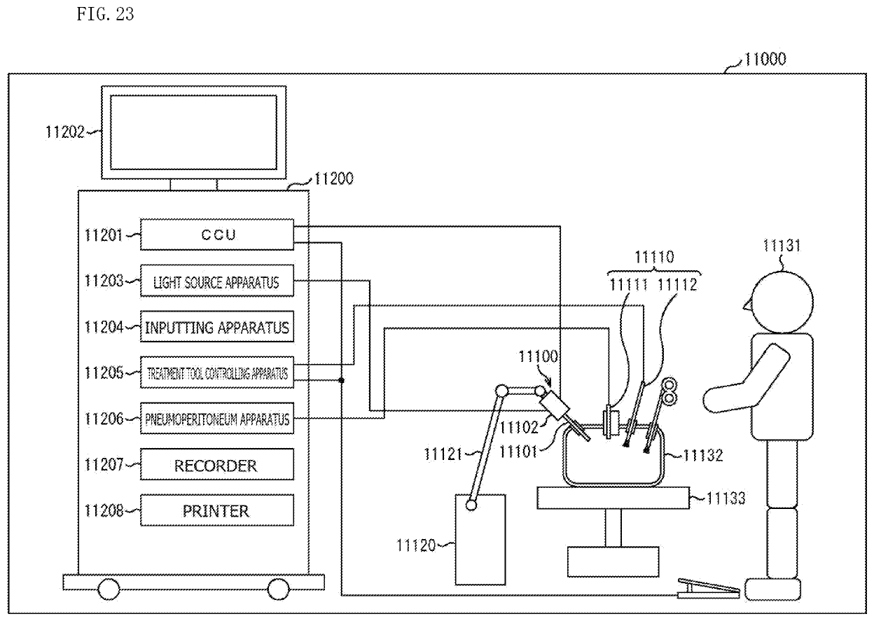

FIG. 23 is a view depicting an example of a schematic configuration of an endoscopic surgery system to which the technology according to an embodiment of the present disclosure (present technology) can be applied.

In FIG. 23, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

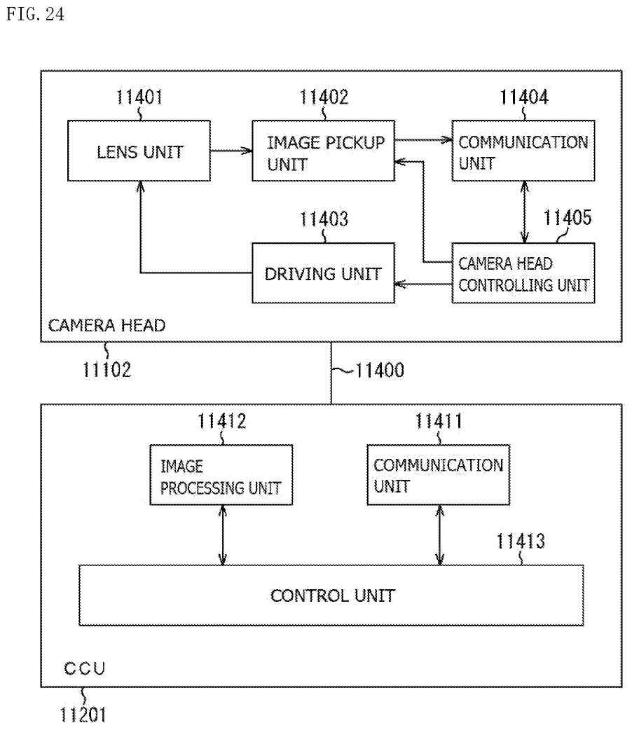

FIG. 24 is a block diagram depicting an example of a functional configuration of the camera head 11102 and the CCU 11201 depicted in FIG. 23.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

In the forgoing, an example of the endoscopic surgery system is described to which the technology according to the present disclosure is applicable. The technology according to the present disclosure is applicable to, for example, the image pick up unit 11402 out of the configuration described above. Applying the technology according to the present disclosure to the image pick up unit 11402 leads to enhancement in detection accuracy.

It is to be noted that the endoscopic surgery system is described here as an example, but the technology according to the present disclosure may be applied to other systems, for example, a micrographic surgery system, etc.

### <Practical Application Examples to Mobile Body>

The technology according to the present disclosure is applicable to various products. For example, the technology according to the present disclosure may be achieved as a device to be installed in any kind of a mobile body such as an automobile, an electric vehicle, a hybrid electric vehicle, a motorcycle, a bicycle, a personal mobility, an aircraft, a drone, a vessel, a robot, construction machinery, and agricultural machinery (tractor).

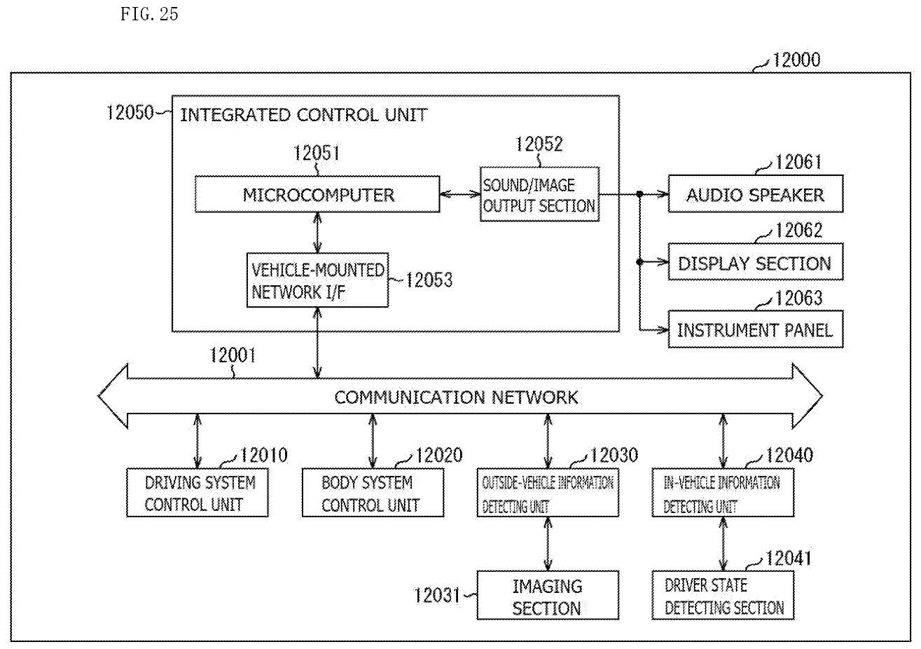

FIG. 25 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 25, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 25, an audio speaker 12061, a display section 12062, and an instrument panel 12063 are illustrated as the output device. The display section 12062 may, for example, include at least one of an on-board display and a head-up display.

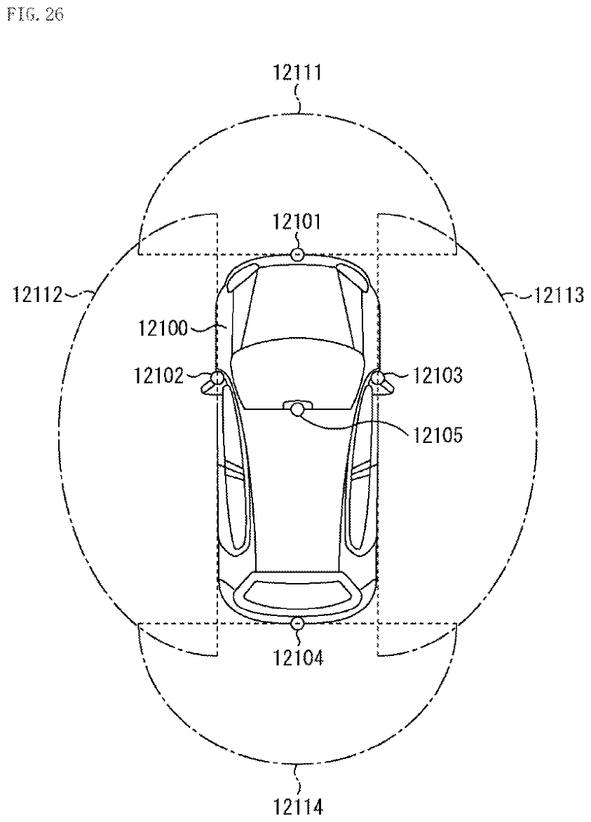

FIG. 26 is a diagram depicting an example of the installation position of the imaging section 12031.

In FIG. 26, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 26 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the forgoing, an example of the vehicle control system is described to which the technology according to the present disclosure is applicable. The technology according to the present disclosure is applicable to the imaging section 12031 out of the configuration described above. Applying the technology according to the present disclosure to the imaging section 12031 makes it possible to obtain images that are easier to see. Hence, it is possible to alleviate a driver's fatigue.

Although contents of the present disclosure have been described above with reference to the embodiments and the modification examples, the contents of the present disclosure are not limited to the forgoing embodiments and the like described above, but may be modified in a variety of ways. For example, the configuration of the imaging device described in the forgoing embodiments and the like is merely illustrative, and may further include other layers. Moreover, a material and a thickness of each layer are also illustrative, and not limited to those described above.

Moreover, in the forgoing first embodiment, the case is described in which the cut portion C is provided from the planarization film 33 to the semiconductor substrate 11. However, it suffices that the cut portion C is provided at least in a thickness direction of the insulating film 31. For example, the cut portion C may be provided in the thickness direction of the planarization film 33 and the insulating film 31, causing the light input surface 21S of the semiconductor substrate 21 to be exposed in the bottom surface of the cut portion C. Alternatively, the cut portion C may be provided from the planarization film 33 to the semiconductor substrate 21, causing the bottom surface of the cut portion C to be provided inside the semiconductor substrate 21.

Moreover, in the forgoing first embodiment, the case is described in which the cut portion C is provided for suppression of intrusion of moisture through the chip end face. In the forgoing second embodiment, the case is described in which the hole portion M is provided for the inspection in the wafer state. However, the functions of the cut portion and the hole portion of the present disclosure are not limited thereto. The shapes and the arrangements of the cut portion and the hole portion of the present disclosure are not limited to those described in the forgoing embodiments and the like.

Furthermore, in the forgoing embodiments and the like, the case is described in which the rewiring 51 is provided in the hole H of the semiconductor substrate 11 (for example, FIG. 2). However, the hole H may be filled with an electrically conductive body separate from the rewiring 51. The electrically conductive body may be coupled to the rewiring 51.

In addition, in the forgoing embodiments and the like, the example is described in which the imaging device 1 includes two stacked chips (the logic chip 10 and the sensor chip 20) (for example, FIG. 2). Besides, the imaging device 1 may include three or more stacked chips.

The effects described in the forgoing embodiments and the like are merely illustrative. The technology according to the present disclosure may produce other effects, or further include other effects.

It is to be noted that the present disclosure may have the following configurations. According to the imaging device having the following configurations, the implanted film is implanted in a portion or all in the depth direction of the cut portion and the hole portion. The implanted film includes the different material from the material of the bonding member. This makes it possible to reduce the thickness of the bonding member between the protective member and the insulating film, as compared to a case where the cut portion or the hole portion is filled with the use of the bonding member. Hence, it is possible to reduce expansion of light reflected from between the semiconductor substrate and the protective member. This leads to suppression of a decrease in image quality caused by flare, etc.

(1)

An imaging device including:

a first semiconductor substrate including a light input surface and provided with a photoelectric conversion section;

a second semiconductor substrate provided on opposite side of the first semiconductor substrate to the light input surface;

an insulating film provided on side of the first semiconductor substrate on which the light input surface is disposed;

a cut portion, a hole portion, or both that extend at least in a thickness direction of the insulating film;

an implanted film implanted in a portion or all in a depth direction of the cut portion, the hole portion, or both;

a protective member opposed to the first semiconductor substrate with the insulating film in between; and

a bonding member including a different material from a material of the implanted film and provided between the protective member and the insulating film.

(2)

The imaging device according to (1) described above, in which the cut portion is provided on a periphery of the insulating film and extends through the insulating film and the first semiconductor substrate.

(3)

The imaging device according to (2) described above, in which the implanted film includes an insulating material.

(4)

The imaging device according to any one of (1) to (3) described above, further including:

a lens opposed to the photoelectric conversion section with the insulating film in between; and

a planarization film that covers the lens and includes a same material as a material of the implanted film.

(5)

The imaging device according to (4) described above, in which a refractive index of the material of the planarization film and the implanted film is lower than a refractive index of a material of the lens.

(6)

The imaging device according to any one of (1) to (5) described above, further including a pad electrode provided between the first semiconductor substrate and the second semiconductor substrate, in which

the hole portion extends through the insulating film and the first semiconductor substrate and reaches the pad electrode.

(7)

The imaging device according to (6) described above, in which the implanted film includes an electrically conductive material.

(8)

The imaging device according to (6) or (7) described above, in which the implanted film includes a metal material.

(9)

The imaging device according to any one of (6) to (8) described above, further including a multilayered wiring layer in which the pad electrode is provided.

(10)

The imaging device according to (9) described above, further including an external coupling terminal electrically coupled to the pad electrode and provided on an opposite surface of the second semiconductor substrate to the multilayered wiring layer.

(11)

The imaging device according to any one of (1) to (10) described above, in which the implanted film is implanted in all in the depth direction of the cut portion, the hole portion, or both.

(12)

The imaging device according to any one of (1) to (10) described above, in which the implanted film is implanted in a portion in the depth direction of the cut portion, the hole portion, or both.

(13)

The imaging device according to any one of (1) to (12) described above, in which the cut portion and the hole portion are provided, and the implanted film is implanted in the cut portion and the hole portion.

(14)

The imaging device according to any one of (1) to (13) described above, in which the cut portion, the hole portion, or both have a width that is gradually reduced in the depth direction.

(15)

The imaging device according to any one of (1) to (14) described above, in which the cut portion, the hole portion, or both have a width that is stepwise reduced in the depth direction.

This application claims the benefit of Japanese Patent Application No. 2019-104223 filed with the Japan Patent Office on Jun. 4, 2019, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. An imaging device, comprising:
a first semiconductor substrate including a light input surface and provided with a photoelectric conversion section;
a second semiconductor substrate provided on opposite side of the first semiconductor substrate to the light input surface;
an insulating film provided on side of the first semiconductor substrate on which the light input surface is disposed;
a cut portion, a hole portion, or both that extend at least in a thickness direction of the insulating film;
an implanted film implanted in a portion or all in a depth direction of the cut portion, the hole portion, or both;
a protective member opposed to the first semiconductor substrate with the insulating film in between; and
a bonding member including a different material from a material of the implanted film and provided between the protective member and the insulating film.

2. The imaging device according to claim 1, wherein the cut portion is provided on a periphery of the insulating film and extends through the insulating film and the first semiconductor substrate.

3. The imaging device according to claim 2, wherein the implanted film includes an insulating material.

4. The imaging device according to claim 1, further comprising:
a lens opposed to the photoelectric conversion section with the insulating film in between; and
a planarization film that covers the lens and includes a same material as a material of the implanted film.

5. The imaging device according to claim 4, wherein a refractive index of the material of the planarization film and the implanted film is lower than a refractive index of a material of the lens.

6. The imaging device according to claim 1, further comprising a pad electrode provided between the first semiconductor substrate and the second semiconductor substrate, wherein
the hole portion extends through the insulating film and the first semiconductor substrate and reaches the pad electrode.

7. The imaging device according to claim 6, wherein the implanted film includes an electrically conductive material.

8. The imaging device according to claim 6, wherein the implanted film includes a metal material.

9. The imaging device according to claim 6, further comprising a multilayered wiring layer in which the pad electrode is provided.

10. The imaging device according to claim 9, further comprising an external coupling terminal electrically coupled to the pad electrode and provided on an opposite surface of the second semiconductor substrate to the multilayered wiring layer.

11. The imaging device according to claim 1, wherein the implanted film is implanted in all in the depth direction of the cut portion, the hole portion, or both.

12. The imaging device according to claim 1, wherein the implanted film is implanted in a portion in the depth direction of the cut portion, the hole portion, or both.

13. The imaging device according to claim 1, wherein the cut portion and the hole portion are provided, and the implanted film is implanted in the cut portion and the hole portion.

14. The imaging device according to claim 1, wherein the cut portion, the hole portion, or both have a width that is gradually reduced in the depth direction.

15. The imaging device according to claim 1, wherein the cut portion, the hole portion, or both have a width that is stepwise reduced in the depth direction.
